(19) United States
(12) Patent Application Publication
(10) Pub. No.: US 2026/0125597 A1
(43) Pub. Date: May 7, 2026

(54) SEMICONDUCTOR NANOPARTICLE, METHOD OF PRODUCING THE SAME AND ELECTRONIC DEVICE INCLUDING THE SAME

(71) Applicant: SAMSUNG ELECTRONICS CO., LTD., Suwon-si (KR)

(72) Inventors: Seon-Yeong KIM, Suwon-si (KR); Minho KIM, Suwon-si (KR); Dae-Yong Son, Suwon-si (KR); Seungrim YANG, Suwon-si (KR); Eun Seog CHO, Suwon-si (KR); Taekhoon KIM, Suwon-si (KR); Soo Kyung KWON, Suwon-si (KR); Tae-Gon KIM, Suwon-si (KR); Nayoun WON, Suwon-si (KR); Sue In CHAE, Suwon-si (KR)

(21) Appl. No.: 19/380,161

(22) Filed: Nov. 5, 2025

(30) Foreign Application Priority Data
Nov. 6, 2024 (KR) 10-2024-0156446

(51) Int. Cl. C09K 11/88; B82Y 20/00; B82Y 40/00; C01B 19/00; G02F 1/13357; H10H 29/85; H10K 50/115; H10K 59/38

(52) U.S. Cl. CPC C09K 11/883; C01B 19/002; H10H 29/8517; H10K 50/115; H10K 59/38; B82Y 20/00; B82Y 40/00; C01P 2006/60; G02F 1/133617

(57) ABSTRACT

A nanoparticle, a method of manufacturing the nanoparticle, a composition including the nanoparticle, a composite including a matrix and a plurality of nanoparticles dispersed in the matrix, a display device including the nanoparticle, and an electronic device including the nanoparticle. The nanoparticle includes a semiconductor nanocrystal including zinc, indium, and selenium. In the semiconductor nanocrystal, a mole ratio of indium to selenium (In:Se) is greater than or equal to about 0.1:1 and less than or equal to about 0.5:1. The nanoparticle does not include cadmium, and the nanoparticle is configured to emit a first light. A peak emission wavelength of the first light is greater than or equal to about 480 nanometers and less than or equal to about 700 nanometers.

### CROSS-REFERENCE TO RELATED APPLICATION

This application is based on and claims priority to Korean Patent Application No. 10-2024-0156446, filed on Nov. 6, 2024, in the Korean Intellectual Property Office, and all the benefits accruing therefrom under 35 U.S.C. § 119, the content of which in its entirety is incorporated herein by reference.

### BACKGROUND

### 1. Field

A semiconductor nanoparticle, a method of producing the semiconductor nanoparticle, a composition including the semiconductor nanoparticle and a liquid vehicle, a semiconductor nanoparticle composite including a matrix and a plurality of nanoparticles dispersed in the matrix, a display device comprising the semiconductor nanoparticle, and an electronic device including the semiconductor nanoparticle are disclosed.

### 2. Description of the Related Art

A semiconductor nanoparticle may exhibit different aspects, characteristics, or properties compared to a corresponding bulk material having substantially the same composition. For example, the semiconductor nanoparticle may have different physical properties based on the nanostructure (e.g., bandgap energy, a luminescent property, or the like). The semiconductor nanoparticle may be configured to emit light upon excitation by incident light or an applied voltage. The luminescent nanostructure may find applicability in a variety of devices (e.g., a display panel or an electronic device including the display panel). From an environmental point of view, developing a luminescent nanoparticle that does not contain a harmful heavy metal such as cadmium, and still achieves comparable or an improvement in one or more luminescent or optical properties is of interest and desirable.

### SUMMARY

An aspect relates to a particle including a semiconductor nanocrystal (hereinafter, also can be referred to as a nanoparticle or a semiconductor nanoparticle) that is configured to emit light of a desired wavelength.

An aspect relates to a manufacturing method for manufacturing the semiconductor nanoparticle or a population thereof.

An aspect relates to a composition (e.g., an ink composition) including the semiconductor nanoparticle or a population thereof.

An aspect relates to a semiconductor nanoparticle composite including the semiconductor nanoparticle or a population thereof.

An aspect relates to a color conversion panel or a display device including the semiconductor nanoparticle or a population thereof.

An aspect relates to an electronic device including the semiconductor nanoparticle or a population thereof, e.g., in a color conversion panel of an electronic device or display device.

In an embodiment, a nanoparticle includes a semiconductor nanocrystal including zinc, indium, and selenium, and in the semiconductor nanocrystal, a mole ratio of indium to selenium is greater than or equal to about 0.1:1 and less than or equal to about 0.5:1, the nanoparticle does not include cadmium, and the nanoparticle is configured to emit a first light, and a peak emission wavelength of the first light is greater than or equal to about 480 nanometers (nm) and less than or equal to about 700 nm.

The semiconductor nanocrystal may include a Group Dec. 13, 2016 compound including (or consisting of) zinc, indium, and selenium.

The semiconductor nanocrystal may not include silver, copper, or a combination thereof.

The semiconductor nanocrystal may not include manganese, cobalt, or a combination thereof.

The semiconductor nanocrystal may have a tetragonal structure.

In the semiconductor nanocrystal or the nanoparticle, a mole ratio of indium to selenium (In:Se) may be greater than or equal to about 0.13:1, or greater than or equal to about 0.2:1.

In the semiconductor nanocrystal or the nanoparticle, a mole ratio of indium to selenium (In:Se) may be less than or equal to about 0.43:1, or less than or equal to about 0.4:1.

In the semiconductor nanocrystal, a mole ratio of indium to selenium (In:Se) may be greater than or equal to about 0.13:1 and less than or equal to about 0.43:1.

In the semiconductor nanocrystal or the nanoparticle, a mole ratio of indium to a total of zinc and indium (In:(Zn+In)) may be greater than or equal to about 0.02:1, or greater than or equal to about 0.09:1 and less than or equal to about 0.8:1, or less than or equal to about 0.75:1.

In the semiconductor nanocrystal, a mole ratio of indium to a total of zinc and indium (In:(Zn+In)) may be greater than or equal to about 0.02:1 and less than or equal to about 0.8:1.

In the semiconductor nanocrystal or the nanoparticle, a mole ratio of indium to a total of zinc and indium may be greater than or equal to about 0.1:1, or greater than or equal to about 0.25:1.

In the semiconductor nanocrystal or the nanoparticle, a mole ratio of indium to a total of zinc and indium (In:(Zn+In)) may be less than or equal to about 0.7:1, less than or equal to about 0.65:1, or less than or equal to about 0.55:1.

In the semiconductor nanocrystal or the nanoparticle, a mole ratio of zinc to selenium (Zn:Se) may be greater than or equal to about 0.35:1, greater than or equal to about 0.4:1, or greater than or equal to about 0.42:1 and less than or equal to about 1.34:1, less than or equal to about 1.2:1, or less than or equal to about 1.1:1.

In the semiconductor nanocrystal or the nanoparticle, a charge balance value obtained by the following formula may be greater than or equal to about 0.8, greater than or equal to about 0.9, or greater than or equal to about 1.3 and less than or equal to about 1.8, less than or equal to about 1.4, less than or equal to about 1.25, or less than or equal to about 1.08:

$$Charge balance value = \{ 2 [ Zn ] + 3 [ ln ] \} / ( 2 [ Se ] )$$

where [Zn], [In], and [Se] are mole amounts of zinc, indium, and selenium, respectively, in the semiconductor nanocrystal or the nanoparticle, respectively.

The first light may be a trap emission. An emission peak of the trap emission may have a full width at half maximum (FWHM) that is greater than or equal to about 70 nm, greater than or equal to about 90 nm, or greater than or equal to about 100 nm. The emission peak of the trap emission may have a full width at half maximum (FWHM) that is less than or equal to about 180 nm, less than or equal to about 150 nm, or less than or equal to about 120 nm.

The first light may have a FWHM of greater than or equal to about 90 nm and less than or equal to about 200 nm, e.g., and the peak emission wavelength of the first light may be greater than or equal to about 500 nm and less than or equal to about 680 nm.

The first light or the trap emission may have a peak emission wavelength that is greater than or equal to about 500 nm, greater than or equal to about 550 nm, greater than or equal to about 580 nm, greater than or equal to about 590 nm, or greater than or equal to about 600 nm. The first light or the trap emission may have a peak emission wavelength less than or equal to about 680 nm, less than or equal to about 650 nm, or less than or equal to about 645 nm.

The nanoparticle may exhibit a first absorption peak in an ultraviolet visible (UV-Vis) absorption spectrum. The nanoparticle may not exhibit a first absorption peak in a UV-Vis absorption spectrum.

In the UV-Vis absorption spectrum, a first absorption peak wavelength of the nanoparticle may be greater than or equal to about 380 nm, greater than or equal to about 390 nm, greater than or equal to about 400 nm, or greater than or equal to about 430 nm. The first absorption peak wavelength of the nanoparticle may be less than or equal to about 550 nm, less than or equal to about 500 nm, or less than or equal to about 490 nm.

In the UV-Vis absorption spectrum, the nanoparticle may exhibit an absorption edge at less than or equal to about 540 nm, less than or equal to about 500 nm, or less than or equal to about 490 nm. The absorption edge may appear at greater than or equal to about 380 nm, greater than or equal to about 390 nm, or greater than or equal to about 400 nm.

In an UV-Vis absorption spectrum, the nanoparticle may have an absorption edge in a range of greater than or equal to about 380 nm and less than or equal to about 540 nm. In an UV-Vis absorption spectrum, the nanoparticle may have a first absorption peak wavelength of greater than or equal to about 380 nm and less than or equal to about 500 nm.

The nanoparticle may have a pyramidal (e.g., tetrahedral) shape.

The nanoparticle may have a particle size that is greater than or equal to about 2 nm, greater than or equal to about 3 nm, greater than or equal to about 4 nm, or greater than or equal to about 5 nm. The nanoparticle may have a particle size less than or equal to about 50 nm, less than or equal to about 40 nm, or less than or equal to about 30 nm.

In an embodiment, a method of manufacturing a nanoparticle or a semiconductor nanocrystal includes contacting (or mixing) an indium precursor, a selenium precursor, and a zinc precursor at a reaction temperature in an organic solvent in the presence of an organic ligand. The reaction temperature is greater than or equal to about 230° C. and less than or equal to about 380° C.

In an embodiment, the method may include preparing a reaction solution including the indium precursor, the selenium precursor, and the organic ligand in the organic solvent; heating the reaction solution to the reaction temperature; and adding the zinc precursor to the reaction solution.

The reaction solution may be pre-treated by heating under vacuum at a temperature of greater than or equal to about 50° C. to less than or equal to about 180° C. before being heated to the reaction temperature. The zinc precursor may be added to the reaction solution when the temperature of the reaction solution is greater than or equal to about 200° C. and less than or equal to the reaction temperature.

The organic solvent may include a primary amine compound of C5 to C40. An amount of the primary amine compound in the organic solvent may be greater than or equal to about 30% and less than or equal to about 100% based on a total volume of the organic solvent. The organic solvent may further include or may not include a hydrocarbon solvent of C5 to C30, a tertiary amine compound of C5 to C40, or a combination thereof.

The reaction temperature may be greater than or equal to about 280° C. and less than or equal to about 320° C.

The reaction solution may not include a dodecanethiol.

The zinc precursor may include a zinc carboxylate, an alkylated zinc, or a combination thereof.

The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, RHPOOH, R₂POOH or a combination thereof, and R and R′ are each independently a substituted or unsubstituted C1 to C40 (or C3 to C24) aliphatic hydrocarbon (e.g., an alkyl group, an alkenyl group, or an alkynyl group), or a substituted or unsubstituted C6 to C40 (or C6 to C24) aromatic hydrocarbon (e.g., a C6 to C20 aryl group).

In an embodiment, an ink composition includes the nanoparticle.

In an embodiment an ink composition may further include a liquid vehicle. The nanoparticle may be dispersed within the liquid vehicle. The liquid vehicle may include a polymerizable (or liquid) monomer, an organic solvent, or a combination thereof. The ink composition may be substantially free of a volatile organic solvent. The ink composition may further include a metal oxide nanoparticle.

An embodiment provides a color conversion layer or a color conversion structure (hereinafter, referred to as a color conversion layer) including the nanoparticle or a color conversion region including the nanoparticle. In an embodiment, a color conversion panel may include a color conversion layer including a color conversion region and, optionally, a partition wall (e.g., a black matrix, a bank, or a pixel defining layer) defining each region of the color conversion layer. The color conversion region includes a first region corresponding to a first pixel, the first region includes a first composite configured to emit a first light, and the first composite may include a matrix and a semiconductor nanoparticle dispersed in the matrix.

An embodiment relates to a display device (or a display panel) including a light source and the nanoparticle (or a composite, a color conversion layer, or a color conversion panel including the same). In an embodiment, the display panel may include a light emitting panel (or a light source), the color conversion panel, and, optionally, a light transmitting layer located between the light emitting panel and the color conversion panel.

In an embodiment, the display device includes the color conversion panel or the display panel.

The light emitting panel (or light source) may be configured to provide incident light to the color conversion layer (or color conversion panel). The incident light may include blue light and, optionally, green light. The blue light may have a peak wavelength in a range of 440 nm to 460 nm or in a range of 450 nm to 455 nm.

The light source may include an organic light emitting diode, a micro LED, a mini LED, a nanorod-based LED, or a combination thereof.

In an embodiment, an electronic device includes a first electrode and a second electrode that are spaced apart from each other; and an active layer disposed between the first electrode and the second electrode, the active layer including the nanoparticle. A charge auxiliary layer (e.g., a hole auxiliary layer) may be located between the first electrode and the active layer.

In an embodiment, the display device may include a display device for augmented reality/virtual reality devices, a portable terminal device, a monitor, a notebook personal computer (PC), a television, an electronic display board, a camera, or a vehicle electronic component.

The nanoparticle of an embodiment may be environmentally friendly and emit light at a desired wavelength.

### BRIEF DESCRIPTION OF THE DRAWINGS

The above and other aspects, features, and advantages of certain exemplary embodiments will be more apparent from the following detailed description taken in conjunction with the accompanying drawings.

FIG. 1 is a flowchart showing pattern formation process (photolithography method) using the ink composition of an embodiment.

FIG. 2 is a flowchart showing a pattern forming process (inkjet method) using the ink composition of an embodiment.

FIG. 3A is a schematic cross-sectional view of a color conversion panel according to an embodiment.

FIG. 3B is a cross-sectional view of an electronic device (or display device) including a color conversion panel according to an embodiment.

FIG. 4A is a perspective view illustrating a display panel including a color conversion panel according to an embodiment.

FIG. 4B is an exploded view of a display device according to an embodiment.

FIG. 4C is a cross-sectional view of the display panel of FIG. 4A.

FIG. 4D is an exploded view of a display panel according to an embodiment.

FIG. 5A is a plan view illustrating a pixel arrangement of the display panel of FIG. 4A.

FIGS. 5B, 5C, 5D, and 5E are cross-sectional views showing light emitting devices, respectively, according to an embodiment.

FIG. 6 is a cross-sectional view of the display panel of FIG. 5A taken along line IV-IV.

FIG. 7 is a schematic cross-sectional view of a display device (e.g., a liquid crystal display device) according to an embodiment.

FIG. 8A illustrates a schematic cross-sectional view of an electronic device according to an embodiment.

FIG. 8B illustrates a schematic cross-sectional view of an electronic device according to an embodiment.

FIG. 8C illustrates a schematic cross-sectional view of an electronic device according to an embodiment.

FIG. 9A illustrates photoluminescence spectra of nanoparticles synthesized in Preparation Example 2 (In 10%), Preparation Example 3 (In 15%), and Comparative Example 1 (In 0%).

FIG. 9B illustrates photoluminescence spectra of nanoparticles synthesized in Preparation Example 4 (In 17%), Preparation Example 5 (In 20%), and Preparation Example 6 (In 23%).

FIGS. 10A and 10B illustrate UV-Vis absorption spectra of nanoparticles synthesized in Preparation Examples 1 to 3 and Comparative Example 1.

FIG. 11A illustrates a transmission electron microscope image of nanoparticles synthesized in Preparation Example 1 (In 5%).

FIG. 11B illustrates a transmission electron microscope image of nanoparticles synthesized in Preparation Example 2 (In 10%).

### DETAILED DESCRIPTION

Advantages and features of the techniques described hereinafter, and methods of achieving them, will become apparent with reference to the exemplary embodiments described below in further detail in conjunction with the accompanying drawings. However, the embodiments should not be construed as being limited to the exemplary embodiments set forth herein. If not defined otherwise, all terms (including technical and scientific terms) as used herein may be defined as commonly understood by one having ordinary skill in the art. The terms defined in a generally-used dictionary may not be interpreted ideally or exaggeratedly unless clearly defined.

In addition, unless explicitly described to the contrary, the word “comprise” and variations such as “comprises” or “comprising,” will be understood to imply the inclusion of stated elements but not the exclusion of any other elements.

In the drawings, the thickness of layers, films, panels, regions, etc., are exaggerated for clarity. Like reference numerals designate like elements throughout the specification.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

As used herein, the singular forms “a,” “an,” and “the” are intended to include the plural forms, including “at least one,” unless the context clearly indicates otherwise. For example, the wording “semiconductor nanoparticle” may refer to a single semiconductor nanoparticle or may refer to a plurality of semiconductor nanoparticles. “At least one” is not to be construed as being limited to “a” or “an.” “Or” means “and/or.” As used herein, the term “and/or” includes any and all combinations of one or more of the associated listed items.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5%, or 3% of the stated value.

As used herein, the expression “not including cadmium (or other harmful heavy metal)” may refer to the case in which a concentration of cadmium (or other harmful heavy metal) may be less than or equal to about 100 parts per million by weight (ppmw), less than or equal to about 50 ppmw, less than or equal to about 10 ppmw, less than or equal to about 1 ppmw, less than or equal to about 0.1 ppmw, less than or equal to about 0.01 ppmw, or about zero. In one or more embodiments, substantially no amount of cadmium (or other harmful heavy metal) may be present or, if present, an amount of cadmium (or other harmful heavy metal) may be less than or equal to a detection limit or as an impurity level of a given analysis tool.

Hereinafter, as used herein, when a definition is not otherwise provided, “substituted” refers to replacement of at least one hydrogen of a compound by a substituent selected from a C1 to C30 alkyl group, a C2 to C30 alkenyl group, a C2 to C30 alkynyl group, a C6 to C30 aryl group, a C7 to C30 alkylaryl group, a C7 to C30 arylalkyl group, a C6 to C30 aryloxy group, a C6 to C30 arylthio group, a C1 to C30 alkoxy group, a C1 to C30 alkylthio group, a C1 to C30 heteroalkyl group, a C3 to C30 heteroalkylaryl group, a C2 to C30 alkylheteroaryl group, a C2 to C30 heteroarylalkyl group, a C1 to C30 heteroaryloxy group, a C1 to C30 heteroarylthio group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group or an amine group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O) OR, wherein R is a C1 to C6 alkyl group or a C6 to C12 aryl group), a carboxyl group (—COOH) or a salt thereof (—C(═O) OM, wherein M is an organic or inorganic cation, a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof. The specified number or range of carbon atoms in a group is exclusive of any substituents.

In addition, when a definition is not otherwise provided below, “hetero” means a case including 1 to 3 heteroatoms such as N, O, P, Si, S, Se, Ge, or B.

In addition, the term “aliphatic hydrocarbon group” as used herein refers to a C1 to C30 linear or branched alkyl group, a C1 to C30 linear or branched alkenyl group, or a C1 to C30 linear or branched alkynyl group, and the term “aromatic organic group” as used herein refers to a C6 to C30 aryl group or a C2 to C30 heteroaryl group.

As used herein, the term “(meth)acrylate” refers to acrylate and/or methacrylate.

As used herein, the term “Group” refers to a Group of Periodic Table.

As used herein, the terms “a nanoparticle” and “a nanostructure” refer to a structure having at least one region or characteristic dimension with a nanoscale dimension. In one or more embodiments, the dimension of the nanoparticle or the nanostructure may be less than about 500 nm, less than about 300 nm, less than about 250 nm, less than about 150 nm, less than about 100 nm, less than about 50 nm, or less than about 30 nm. The nanoparticle or nanostructure may have any shape, such as a nanowire, a nanorod, a nanotube, a multi-pod type shape having two or more pods, a nanodot, or the like, but embodiments are not limited thereto. The nanoparticle or nanostructure may be, for example, substantially crystalline, substantially monocrystalline, polycrystalline, amorphous, or a combination thereof.

A quantum dot may be, for example, a semiconductor-containing nanocrystal particle that can exhibit a quantum confinement or exciton confinement effect, and is a type of a luminescent nanostructure (e.g., capable of emitting light by energy excitation). Herein, a shape of the “quantum dot” or the nanoparticle is not limited unless otherwise expressly defined.

As used herein, the term “dispersion” refers to a dispersion in which a dispersed phase is a solid, and a continuous medium includes a liquid or a solid different from the dispersed phase. It is to be understood that the “dispersion” may be a colloidal dispersion in which the dispersed phase has a dimension of greater than or equal to about 1 nm, for example, greater than or equal to about 2 nm, greater than or equal to about 3 nm, or greater than or equal to about 4 nm and less than or equal to several micrometers (μm), (e.g., less than or equal to about 2 μm, less than or equal to about 1 μm, less than or equal to about 900 nm, less than or equal to about 800 nm, less than or equal to about 700 nm, less than or equal to about 600 nm, or less than or equal to about 500 nm).

Herein, a dimension (a size, a diameter, or a thickness, etc.) may be a value for a single entity or an average value for a plurality of nanoparticles. As used herein, the term “average” (e.g., an average size of the quantum dot) may be a mean value or a median value. In one or more embodiments, the average may be “mean” average.

As used herein, the term “maximum emission wavelength (or peak emission wavelength)” is the wavelength at which a given emission spectrum of the light reaches its maximum.

In one or more embodiments, a quantum efficiency may be readily and reproducibly determined using commercially available equipment (e.g., from Hitachi or Hamamatsu, etc.) and referring to manuals provided by, for example, respective equipment manufacturers. The quantum efficiency (which can be interchangeably used with the term “quantum yield” (QY)) may be measured in a solution state or a solid state (i.e., in a composite). In one or more embodiments, the quantum efficiency (or the quantum yield) is the ratio of photons emitted to photons absorbed by the nanostructure or population thereof. In one or more embodiments, the quantum efficiency may be measured by any method. For example, there may be two methods for measuring the fluorescence quantum yield or efficiency: the absolute method and the relative method. The quantum efficiency measured by the absolute method may be referred to as an absolute quantum efficiency.

In the absolute method, the quantum efficiency may be obtained by detecting the fluorescence of all samples through an integrating sphere. In the relative method, the quantum efficiency of the unknown sample may be calculated by comparing the fluorescence intensity of a standard dye (a standard sample) with the fluorescence intensity of the unknown sample. Coumarin 153, Coumarin 545, Rhodamine 101 inner salt, Anthracene and Rhodamine 6G may be used as standard dyes according to their photoluminescence (PL) wavelengths, but embodiments are not limited thereto.

A full width at half maximum (FWHM) and a peak emission (e.g., photoluminescence (PL) or electroluminescence (EL)) wavelength may be measured, for example, from a luminescence spectrum (for example, a photoluminescence spectrum or an electroluminescent spectrum) obtained by a spectrophotometer such as a fluorescence spectrophotometer or the like.

As used herein, the term “first absorption peak wavelength” refers to a wavelength at which a main peak first appears in a lowest energy region in the ultraviolet-visible (UV-Vis) absorption spectrum.

A semiconductor nanoparticle may be used in various electronic devices, for example, also in a color conversion panel (or an emissive color filter). A liquid crystal display device may include a white light-emitting backlight unit and an absorptive color filter, and the backlight unit may include a quantum dot sheet. In a display device including a quantum dot-based color conversion panel or an emissive color filter, a quantum dot layer as an emission material is disposed at the front of the device, and blue light (excitation light) provided from a light source is converted into green light or red light by the quantum dot layer. In the color conversion panel, the color conversion of incident light may occur at a relatively front portion of the device, and a wide viewing angle may be implemented by omnidirectional scattering of light. The emissive color filter may realize a reduction in light loss. The color conversion panel may be an electronic device including a color conversion layer or a color conversion structure.

An optical sensor may be used in various electronic devices such as optical communication flexible touchscreens, camera exposure meters, automatic flash devices, photoelectric switches, barcode readers, image scanners, and medical analyzers. Nanoparticles such as quantum dots have potential applicability as materials in optical sensors in that they allow selection of a desired wavelength band of a light receiving region. An optical sensor including nanoparticles such as quantum dots may absorb and emit light of a specific wavelength and, for example, may exhibit relatively high emission efficiency along with an increased absorption coefficient, thereby having applicability in optoelectronic devices.

Many semiconductor nanoparticles (e.g., quantum dots) having luminescent properties at a practically applicable level are based on toxic heavy metals such as cadmium (Cd), lead (Pb), and/or mercury (Hg). Toxic heavy metals such as cadmium raise serious environmental and health concerns and are regulated elements under the Restriction of Hazardous Substances (RoHS) directives in many countries. Therefore, it is desirable to develop environmentally friendly quantum dots that can emit light at a desired wavelength while exhibiting enhanced optical properties (e.g., when applied to various electronic devices).

In an embodiment, the nanoparticle may not include cadmium. The nanoparticle may not include mercury, lead, or a combination thereof. In an embodiment, the nanoparticle (hereinafter, that can be referred to as semiconductor nanoparticle) includes a semiconductor nanocrystal including zinc, indium, and selenium, and in the semiconductor nanocrystal, a mole ratio of indium to selenium is greater than or equal to about 0.1:1 and less than or equal to about 0.5:1, the nanoparticle does not include cadmium, and the nanoparticle is configured to emit a first light. The semiconductor nanocrystal may include a Group Dec. 13, 2016 compound including (or consisting of) zinc, indium, and selenium.

As a Group Dec. 13, 2016 compound, zinc indium selenide may have a direct bandgap energy of about 1.82 electron volts (eV). A zinc indium selenide may be synthesized in a thin-film form or in a bulk crystal form, but it is difficult to manufacture as semiconductor nanoparticles (e.g., quantum dots) having a small particle size (e.g., monodisperse). Therefore, a nanoparticle including a zinc indium selenide may exhibit optical properties through additional metals (for example, by doping with additional metals such as copper, silver, or manganese). However, in the case of emission based on such doping, the emission may be different from the emission based on the characteristics of zinc indium selenide itself.

The nanoparticle of an embodiment may exhibit an emission characteristic based on a zinc indium selenide itself by having a feature defined herein. Therefore, in an embodiment, the semiconductor nanocrystal or the nanoparticle including the same may not include silver, copper, or a combination thereof. The semiconductor nanocrystal or the nanoparticle including the same may not include manganese, cobalt, or a combination thereof. In an embodiment, the semiconductor nanocrystal may have a tetragonal crystal structure. Zinc indium selenide in a tetragonal crystal structure may have a lattice constant a of about 5.75 angstrom and a lattice constant c of about 11.63 angstrom.

In the semiconductor nanocrystal or the nanoparticle, a mole ratio of indium to selenium (In:Se) may be greater than or equal to about 0.11:1, greater than or equal to about 0.13:1, greater than or equal to about 0.15:1, greater than or equal to about 0.17:1, greater than or equal to about 0.19:1, greater than or equal to about 0.2:1, greater than or equal to about 0.21:1, greater than or equal to about 0.23:1, greater than or equal to about 0.25:1, greater than or equal to about 0.27:1, greater than or equal to about 0.29:1, greater than or equal to about 0.3:1, greater than or equal to about 0.31:1, greater than or equal to about 0.33:1, greater than or equal to about 0.35:1, greater than or equal to about 0.37:1, or greater than or equal to about 0.39:1. In the semiconductor nanocrystal or the nanoparticle, a mole ratio of indium to selenium (In:Se) may be less than or equal to about 0.49:1, less than or equal to about 0.48:1, less than or equal to about 0.47:1, less than or equal to about 0.45:1, less than or equal to about 0.43:1, less than or equal to about 0.42:1, less than or equal to about 0.41:1, less than or equal to about 0.4:1, less than or equal to about 0.39:1, less than or equal to about 0.38:1, less than or equal to about 0.36:1, less than or equal to about 0.34:1, less than or equal to about 0.32:1, or less than or equal to about 0.28:1.

In the semiconductor nanocrystal or the nanoparticle, a mole ratio of indium to a total of zinc and indium (In:(Zn+In)) may be greater than or equal to about 0.017:1, greater than or equal to about 0.02:1, greater than or equal to about 0.025:1, greater than or equal to about 0.03:1, greater than or equal to about 0.05:1, greater than or equal to about 0.07:1, greater than or equal to about 0.09:1, greater than or equal to about 0.1:1, greater than or equal to about 0.109:1, greater than or equal to about 0.11:1, greater than or equal to about 0.13:1, greater than or equal to about 0.15:1, greater than or equal to about 0.17:1, greater than or equal to about 0.19:1, greater than or equal to about 0.2:1, greater than or equal to about 0.21:1, greater than or equal to about 0.22:1, greater than or equal to about 0.23:1, greater than or equal to about 0.25:1, greater than or equal to about 0.27:1, greater than or equal to about 0.28:1, greater than or equal to about 0.29:1, greater than or equal to about 0.3:1, greater than or equal to about 0.31:1, greater than or equal to about 0.33:1, greater than or equal to about 0.35:1, greater than or equal to about 0.36:1, greater than or equal to about 0.37:1, greater than or equal to about 0.39:1, greater than or equal to about 0.4:1, greater than or equal to about 0.41:1, greater than or equal to about 0.43:1, greater than or equal to about 0.45:1, greater than or equal to about 0.47:1, or greater than or equal to about 0.49:1. In the semiconductor nanocrystal or the nanoparticle, a mole ratio of indium to a total of zinc and indium (In:(Zn+In)) may be less than or equal to about 0.8:1, less than or equal to about 0.75:1, less than or equal to about 0.7:1, less than or equal to about 0.65:1, less than or equal to about 0.6:1, less than or equal to about 0.55:1, less than or equal to about 0.5:1, or less than or equal to about 0.48:1.

In the semiconductor nanocrystal or the nanoparticle, a mole ratio of zinc to indium (Zn: In) may be greater than or equal to about 0.9:1, greater than or equal to about 0.95:1, greater than or equal to about 0.99:1, greater than or equal to about 1:1, greater than or equal to about 1.1:1, greater than or equal to about 1.15:1, greater than or equal to about 1.2:1, greater than or equal to about 1.25:1, greater than or equal to about 1.3:1, greater than or equal to about 1.35:1, greater than or equal to about 1.4:1, greater than or equal to about 1.45:1, greater than or equal to about 1.5:1, greater than or equal to about 1.6:1, greater than or equal to about 1.65:1, greater than or equal to about 1.7:1, or greater than or equal to about 1.75:1. In the semiconductor nanocrystal or the nanoparticle, a mole ratio of zinc to indium (Zn: In) may be less than or equal to about 12:1, less than or equal to about 10:1, less than or equal to about 9:1, less than or equal to about 8.8:1, less than or equal to about 8.4:1, less than or equal to about 8:1, less than or equal to about 7.5:1, less than or equal to about 7:1, less than or equal to about 6.5:1, less than or equal to about 6:1, less than or equal to about 5.5:1, less than or equal to about 5:1, less than or equal to about 4.8:1, less than or equal to about 4.6:1, less than or equal to about 4.4:1, less than or equal to about 4.2:1, less than or equal to about 4:1, less than or equal to about 3.8:1, less than or equal to about 3.6:1, less than or equal to about 3.4:1, less than or equal to about 3.2:1, less than or equal to about 3:1, less than or equal to about 2.8:1, less than or equal to about 2.6:1, or less than or equal to about 2.4:1.

In the semiconductor nanocrystal or the nanoparticle, a mole ratio of zinc to selenium (Zn:Se) may be greater than or equal to about 0.38:1, greater than or equal to about 0.4:1, greater than or equal to about 0.41:1, greater than or equal to about 0.42:1, greater than or equal to about 0.44:1, greater than or equal to about 0.46:1, greater than or equal to about 0.48:1, greater than or equal to about 0.5:1, greater than or equal to about 0.52:1, greater than or equal to about 0.54:1, greater than or equal to about 0.56:1, greater than or equal to about 0.58:1, greater than or equal to about 0.6:1, greater than or equal to about 0.62:1, greater than or equal to about 0.64:1, greater than or equal to about 0.66:1, greater than or equal to about 0.68:1, greater than or equal to about 0.7:1, greater than or equal to about 0.72:1, greater than or equal to about 0.74:1, greater than or equal to about 0.78:1, or greater than or equal to about 0.8:1. In the semiconductor nanocrystal or the nanoparticle, a mole ratio of zinc to selenium (Zn:Se) may be less than or equal to about 1.5:1, less than or equal to about 1.45:1, less than or equal to about 1.4:1, less than or equal to about 1.36:1, less than or equal to about 1.34:1, less than or equal to about 1.3:1, less than or equal to about 1.25:1, less than or equal to about 1.2:1, less than or equal to about 1.15:1, less than or equal to about 1.1:1, less than or equal to about 1.06:1, less than or equal to about 1.04:1, less than or equal to about 1:1, less than or equal to about 0.9:1, less than or equal to about 0.8:1, or less than or equal to about 0.75:1.

In the semiconductor nanocrystal or the nanoparticle, a charge balance value obtained by the following equation may be greater than or equal to about 0.8, greater than or equal to about 0.83, greater than or equal to about 0.85, greater than or equal to about 0.87, greater than or equal to about 0.9, greater than or equal to about 0.91, greater than or equal to about 0.93, greater than or equal to about 0.95, greater than or equal to about 0.97, greater than or equal to about 0.99, greater than or equal to about 1, greater than or equal to about 1.01, greater than or equal to about 1.03, greater than or equal to about 1.05, greater than or equal to about 1.07, greater than or equal to about 1.09, greater than or equal to about 1.1, greater than or equal to about 1.13, greater than or equal to about 1.15, greater than or equal to about 1.17, greater than or equal to about 1.2, greater than or equal to about 1.23, greater than or equal to about 1.25, greater than or equal to about 1.27, or greater than or equal to about 1.3:

$$Charge balance value = \{ 2 \times [ Zn ] + 3 \times [ ln ] \} / ( 2 \times [ Se ] )$$

where [Zn], [In], and [Se] are mole amounts of zinc, indium, and selenium in the semiconductor nanocrystal or the nanoparticle, respectively.

The charge balance value may be less than or equal to about 1.9, less than or equal to about 1.85, less than or equal to about 1.8, less than or equal to about 1.75, less than or equal to about 1.6, less than or equal to about 1.55, less than or equal to about 1.5, less than or equal to about 1.45, less than or equal to about 1.4, less than or equal to about 1.35, less than or equal to about 1.3, less than or equal to about 1.25, less than or equal to about 1.2, less than or equal to about 1.15, or less than or equal to about 1.1.

The semiconductor nanocrystal may have an amount of indium of greater than or equal to about 3 atomic %, greater than or equal to about 5 atomic %, greater than or equal to about 7 atomic %, greater than or equal to about 9 atomic %, greater than or equal to about 10 atomic %, greater than or equal to about 11 atomic %, greater than or equal to about 12 atomic %, greater than or equal to about 13 atomic %, greater than or equal to about 14 atomic %, greater than or equal to about 15 atomic %, greater than or equal to about 16 atomic %, greater than or equal to about 17 atomic %, greater than or equal to about 18 atomic %, greater than or equal to about 19 atomic %, greater than or equal to about 20 atomic %, greater than or equal to about 21 atomic %, greater than or equal to about 22 atomic %, greater than or equal to about 23 atomic %, greater than or equal to about 24 atomic %, or greater than or equal to about 25 atomic %, based on a total amount of indium, zinc, and selenium. The semiconductor nanocrystal may have an amount of indium of less than or equal to about 50 atomic %, less than or equal to about 40 atomic %, less than or equal to about 35 atomic %, less than or equal to about 30 atomic %, less than or equal to about 28 atomic %, less than or equal to about 25 atomic %, or less than or equal to about 23 atomic %, based on a total amount of indium, zinc, and selenium.

In the related art, a crystal including a zinc indium selenide and having a nano-size has included a dopant in order to emit light of a desired wavelength. The dopant may include copper, silver, manganese, cobalt, and the like. Surprisingly, the present inventors have found that a zinc indium selenide-containing semiconductor nanocrystal according to an embodiment may emit light of a desired wavelength by varying its composition as described herein, even in the absence of such a dopant. In an embodiment, the semiconductor nanocrystal may be synthesized as described herein and may exhibit a composition described herein (e.g., a mole ratio between components or a combination thereof).

In an embodiment, by controlling an indium content with respect to selenium (and/or an indium content with respect to zinc) in a semiconductor nanocrystal or a nanoparticle as described herein, it is possible to control an emission wavelength of the semiconductor nanocrystal or a nanoparticle including the same. A change in the relative indium content (e.g., with respect to selenium or zinc) may cause a change in trap emission in the semiconductor nanocrystal. While a zinc selenide may exhibit band-edge emission in a range of 390 nm to 400 nm, in the semiconductor nanocrystal of an embodiment, an increase in an indium content may cause a trap emission having a peak emission wavelength of greater than or equal to about 600 nm and an increase in its intensity, which may indicate a change in bandgap energy of the semiconductor nanocrystal.

Without wishing to be bound by any theory, such trap emission in the wavelength range is thought to indicate that a nanoparticle including the semiconductor nanocrystal may exhibit a peak emission wavelength in a wavelength region of green light. For example, when an indium content is 25 atomic % based on a total of elements of the semiconductor nanocrystal, trap emission at about 665 nm may be observed. In the semiconductor nanocrystal of an embodiment, an increase in the indium content may lead to a decrease in bandgap energy of the semiconductor nanocrystal. For example, while a semiconductor nanocrystal made of zinc selenide may have a bandgap energy of about 3.12 eV, surprisingly, the present inventors have found that in the semiconductor nanocrystal of an embodiment, when the indium content is varied to 1 atomic %, 5 atomic %, 10 atomic %, or 25 atomic % based on a total amount of indium, zinc, and selenium, the bandgap may change to about 3.05 eV, about 2.90 eV, about 2.80 eV, and about 2.48 eV, respectively, and the trap emission peak increases.

That is, in a UV-Vis absorption spectrum, the semiconductor nanocrystal of an embodiment or a nanoparticle including the same may exhibit an absorption edge wavelength that varies depending on an indium content ratio. The absorption edge or the band edge generally refers to a transition between a strong short-wavelength absorption and a weak long-wavelength absorption in a spectrum of a solid semiconductor. The semiconductor nanocrystal or the nanoparticle including the same may exhibit an absorption edge wavelength that is less than or equal to about 540 nm, less than or equal to about 535 nm, less than or equal to about 530 nm, less than or equal to about 520 nm, less than or equal to about 515 nm, less than or equal to about 510 nm, less than or equal to about 505 nm, less than or equal to about 500 nm, less than or equal to about 495 nm, or less than or equal to about 490 nm. The absorption edge may appear at greater than or equal to about 380 nm, greater than or equal to about 385 nm, greater than or equal to about 390 nm, greater than or equal to about 395 nm, or greater than or equal to about 400 nm. In the semiconductor nanocrystal of an embodiment, when the indium content is varied to 1 atomic %, 5 atomic %, 10 atomic %, or 25 atomic % based on a total amount of indium, zinc, and selenium, the absorption edge wavelength may change to about 406 nm, about 427 nm, about 442 nm, and about 499 nm, respectively.

Accordingly, in an embodiment, the semiconductor nanocrystal or a nanoparticle including the same may emit a first light for example even without an additional dopant. The first light may be a trap emission. The first light may be a band-edge emission. The first light or the trap emission may have a peak emission wavelength of greater than or equal to about 500 nm, greater than or equal to about 505 nm, greater than or equal to about 510 nm, greater than or equal to about 515 nm, greater than or equal to about 520 nm, greater than or equal to about 525 nm, greater than or equal to about 530 nm, greater than or equal to about 535 nm, greater than or equal to about 540 nm, greater than or equal to about 545 nm, greater than or equal to about 550 nm, greater than or equal to about 555 nm, greater than or equal to about 560 nm, greater than or equal to about 570 nm, greater than or equal to about 580 nm, greater than or equal to about 590 nm, or greater than or equal to about 600 nm. The first light or the trap emission may have a peak emission wavelength of less than or equal to about 800 nm, less than or equal to about 780 nm, less than or equal to about 750 nm, less than or equal to about 720 nm, less than or equal to about 700 nm, less than or equal to about 690 nm, less than or equal to about 685 nm, less than or equal to about 680 nm, less than or equal to about 675 nm, less than or equal to about 670 nm, less than or equal to about 665 nm, less than or equal to about 660 nm, less than or equal to about 655 nm, less than or equal to about 650 nm, less than or equal to about 645 nm, less than or equal to about 640 nm, less than or equal to about 635 nm, less than or equal to about 630 nm, less than or equal to about 625 nm, less than or equal to about 620 nm, less than or equal to about 615 nm, less than or equal to about 610 nm, less than or equal to about 605 nm, less than or equal to about 600 nm, less than or equal to about 590 nm, less than or equal to about 585 nm, less than or equal to about 570 nm, or less than or equal to about 560 nm.

The first light may have a peak emission with a full width at half maximum (FWHM) in a range of about 5 nm to about 200 nm, about 10 nm to about 150 nm, about 20 nm to about 130 nm, about 30 nm to about 110 nm, about 35 nm to about 105 nm, about 40 nm to about 100 nm, about 45 nm to about 95 nm, about 50 nm to about 90 nm, about 55 nm to about 85 nm, about 60 nm to about 80 nm, about 65 nm to about 75 nm, about 68 nm to about 70 nm, or a combination thereof.

In an embodiment, the first light may be a trap emission, and the trap emission peak may have a full width at half maximum of greater than or equal to about 50 nm, greater than or equal to about 55 nm, greater than or equal to about 60 nm, greater than or equal to about 65 nm, greater than or equal to about 70 nm, greater than or equal to about 75 nm, greater than or equal to about 80 nm, greater than or equal to about 85 nm, greater than or equal to about 90 nm, greater than or equal to about 95 nm, or greater than or equal to about 100 nm. The full width at half maximum of the trap emission peak may be less than or equal to about 200 nm, less than or equal to about 180 nm, less than or equal to about 170 nm, less than or equal to about 160 nm, less than or equal to about 150 nm, less than or equal to about 140 nm, less than or equal to about 130 nm, or less than or equal to about 120 nm.

In an embodiment, the semiconductor nanocrystal or a nanoparticle including the same may exhibit a first absorption peak or a first excitonic peak in a UV-Vis absorption spectrum. The first absorption peak or the first excitonic peak may refer to the lowest energy transition associated with an exciton, which is a bound electron-hole pair representing a fundamental optical excitation in a semiconductor. Such a peak is associated with the optical property of various materials including a nanoparticle. A first absorption peak wavelength or a first excitonic peak wavelength is a wavelength at which the first absorption peak or the first excitonic peak exhibits the maximum absorbance. The first absorption peak wavelength or the first excitonic peak wavelength can be determined as the point where the first derivative of the UV spectrum equals zero; if there is no point where the first derivative is zero, it can be defined as the point where the second derivative changes from negative to positive between the maximum and minimum values of the first derivative graph. In the UV-Vis absorption spectrum of the nanoparticle or the semiconductor nanocrystal, the first absorption peak wavelength may be greater than or equal to about 370 nm, greater than or equal to about 375 nm, greater than or equal to about 380 nm, greater than or equal to about 385 nm, greater than or equal to about 390 nm, greater than or equal to about 395 nm, greater than or equal to about 400 nm, greater than or equal to about 405 nm, greater than or equal to about 410 nm, greater than or equal to about 415 nm, greater than or equal to about 420 nm, greater than or equal to about 425 nm, greater than or equal to about 430 nm, greater than or equal to about 435 nm, greater than or equal to about 440 nm, greater than or equal to about 445 nm, greater than or equal to about 450 nm, greater than or equal to about 455 nm, greater than or equal to about 460 nm, greater than or equal to about 465 nm, greater than or equal to about 470 nm, greater than or equal to about 475 nm, greater than or equal to about 480 nm, greater than or equal to about 485 nm, greater than or equal to about 490 nm, greater than or equal to about 495 nm, greater than or equal to about 500 nm, greater than or equal to about 505 nm, greater than or equal to about 510 nm, or greater than or equal to about 515 nm. The first absorption peak wavelength of the nanoparticle or the semiconductor nanocrystal may be less than or equal to about 530 nm, less than or equal to about 526 nm, less than or equal to about 521 nm, less than or equal to about 516 nm, less than or equal to about 511 nm, less than or equal to about 506 nm, less than or equal to about 501 nm, less than or equal to about 496 nm, less than or equal to about 491 nm, or less than or equal to about 486 nm.

The semiconductor nanocrystal may have a tetragonal crystal structure, and the nanoparticle or the semiconductor nanocrystal may exhibit, for example, a tetrahedral shape or a pyramidal shape when observed with a transmission electron microscope. The present inventors have found that the indium content in the semiconductor nanocrystal may also affect a morphology of the semiconductor nanocrystal or a nanoparticle including the same. The semiconductor nanocrystal or the nanoparticle including the same of an embodiment may exhibit an increased crystallinity as the indium content increases. The increased crystallinity may lead to self-assembly, but is not limited thereto.

In an embodiment, the semiconductor nanocrystal may have a size (or an average size) that is greater than or equal to about 3 nm, greater than or equal to about 3.5 nm, greater than or equal to about 4 nm, greater than or equal to about 4.5 nm, greater than or equal to about 5 nm, greater than or equal to about 5.5 nm, greater than or equal to about 6 nm, greater than or equal to about 6.5 nm, greater than or equal to about 7 nm, greater than or equal to about 7.5 nm, greater than or equal to about 8 nm, greater than or equal to about 8.5 nm, greater than or equal to about 9 nm, greater than or equal to about 9.5 nm, greater than or equal to about 10 nm, or greater than or equal to about 10.5 nm. The size of the semiconductor nanocrystal may be less than or equal to about 50 nm, less than or equal to about 48 nm, less than or equal to about 46 nm, less than or equal to about 44 nm, less than or equal to about 42 nm, less than or equal to about 40 nm, less than or equal to about 35 nm, less than or equal to about 30 nm, less than or equal to about 25 nm, less than or equal to about 20 nm, less than or equal to about 18 nm, less than or equal to about 16 nm, less than or equal to about 14 nm, less than or equal to about 12 nm, less than or equal to about 11 nm, less than or equal to about 10 nm, less than or equal to about 8 nm, less than or equal to about 7 nm, less than or equal to about 6 nm, or less than or equal to about 4 nm.

In an embodiment, the nanoparticle may further include a layer (for example, a shell) disposed on the semiconductor nanocrystal. The shell may be a multilayer shell. The shell may include a semiconductor nanocrystal (hereinafter also referred to as a second semiconductor nanocrystal) having a different composition from the semiconductor nanocrystal (hereinafter also referred to as a first semiconductor nanocrystal). The semiconductor nanocrystal included in the shell may include a Group 12-16 compound. The Group 12-16 compound may include a zinc chalcogenide (for example, a zinc selenide, a zinc sulfide, a zinc selenide sulfide, or a combination thereof).

A thickness of the shell may be appropriately selected. In an embodiment, the shell may have a thickness greater than or equal to about 0.1 nm, greater than or equal to about 0.3 nm, greater than or equal to about 0.5 nm, greater than or equal to about 0.7 nm, or greater than or equal to about 1 nm. The thickness of the shell may be less than or equal to about 2 nm, less than or equal to about 1.5 nm, less than or equal to about 1 nm, or less than or equal to about 0.8 nm. The thickness of the shell may be in a range of about 0.1 nm to about 5 nm, about 0.2 nm to about 4 nm, about 0.3 nm to about 3.5 nm, about 0.4 nm to about 3 nm, about 0.5 nm to about 2.5 nm, about 0.6 nm to about 2 nm, about 0.7 nm to about 1.5 nm, about 0.8 nm to about 1.2 nm, about 0.9 nm to about 1 nm, or a combination thereof.

In an embodiment, the nanoparticle may have a size (or an average size) greater than or equal to about 3 nm, greater than or equal to about 3.5 nm, greater than or equal to about 4 nm, greater than or equal to about 4.5 nm, greater than or equal to about 5 nm, greater than or equal to about 5.5 nm, greater than or equal to about 6 nm, greater than or equal to about 6.5 nm, greater than or equal to about 7 nm, greater than or equal to about 7.5 nm, greater than or equal to about 8 nm, greater than or equal to about 8.5 nm, greater than or equal to about 9 nm, greater than or equal to about 9.5 nm, greater than or equal to about 10 nm, or greater than or equal to about 10.5 nm. The size of the nanoparticle may be less than or equal to about 50 nm, less than or equal to about 48 nm, less than or equal to about 46 nm, less than or equal to about 44 nm, less than or equal to about 42 nm, less than or equal to about 40 nm, less than or equal to about 35 nm, less than or equal to about 30 nm, less than or equal to about 25 nm, less than or equal to about 20 nm, less than or equal to about 18 nm, less than or equal to about 16 nm, less than or equal to about 14 nm, less than or equal to about 12 nm, less than or equal to about 11 nm, less than or equal to about 10 nm, less than or equal to about 8 nm, less than or equal to about 7 nm, less than or equal to about 6 nm, or less than or equal to about 4 nm.

As used herein, the size of the semiconductor nanocrystal or the nanoparticle may be a particle diameter. The size of the semiconductor nanocrystal or the nanoparticle may be obtained from an image confirmed by electron microscopy (for example, transmission electron microscopy) analysis. The size of the semiconductor nanocrystal or the nanoparticle may be an equivalent diameter obtained by a calculation involving converting a two-dimensional area of a particle obtained from an electron microscope image into a circle. Such a size may be reproducibly and easily obtained from a microscope image using various image processing programs (for example, Image J or an in-house program that may be created using a coding language). The particle size may be a value (for example, a nominal particle size) calculated from a composition of a semiconductor nanoparticle and a peak emission wavelength.

The semiconductor nanocrystal of an embodiment may be obtained by the method described herein. In an embodiment, a method of manufacturing a nanoparticle or a semiconductor nanocrystal includes contacting an indium precursor, a selenium precursor, and a zinc precursor at a reaction temperature in an organic solvent in the presence of an organic ligand. The reaction temperature is greater than or equal to about 230° C. and less than or equal to about 380° C. The inventors have surprisingly confirmed that the semiconductor nanocrystal or the nanoparticle including the same, manufactured by the method described herein, may emit light of a desired wavelength even without introducing an additional metal dopant (for example, copper, silver, cobalt, manganese, etc.).

In an embodiment, the method or the contacting may include preparing a reaction solution including an indium precursor, a selenium precursor, and an organic ligand in an organic solvent; heating the reaction solution to the reaction temperature; and adding a zinc precursor to the reaction solution. In an embodiment, the method or the contacting may include preparing a reaction solution including an indium precursor, a zinc precursor, and an organic ligand in an organic solvent; heating the reaction solution to the reaction temperature; and adding a selenium precursor to the reaction solution.

The reaction solution may be subjected to a pretreatment at a predetermined temperature, for example under vacuum, before being heated to the reaction temperature. The predetermined temperature for the pretreatment may be greater than or equal to about 50° C., greater than or equal to about 60° C., greater than or equal to about 70° C., greater than or equal to about 80° C., greater than or equal to about 90° C., greater than or equal to about 100° C., greater than or equal to about 110° C., or greater than or equal to about 120° C. The predetermined temperature for the pretreatment may be less than or equal to about 180° C., less than or equal to about 170° C., less than or equal to about 160° C., less than or equal to about 150° C., less than or equal to about 140° C., or less than or equal to about 130° C. The pretreatment time is not particularly limited and may be determined in consideration of the type of precursor and the predetermined temperature for the pretreatment. The pretreatment time may be greater than or equal to about 5 minutes, greater than or equal to about 10 minutes, or greater than or equal to about 15 minutes, and less than or equal to about 100 minutes, less than or equal to about 50 minutes, or less than or equal to about 30 minutes, but is not limited thereto.

The zinc precursor may be added to the reaction solution at a first temperature. The selenium precursor may be added to the reaction solution at the first temperature. The first temperature may be greater than or equal to about 120° C., greater than or equal to about 130° C., greater than or equal to about 140° C., greater than or equal to about 150° C., greater than or equal to about 160° C., greater than or equal to about 170° C., greater than or equal to about 180° C., greater than or equal to about 190° C., greater than or equal to about 200° C., greater than or equal to about 210° C., or greater than or equal to about 220° C. The first temperature may be less than or equal to the reaction temperature, for example, less than or equal to about 300° C., less than or equal to about 290° C., less than or equal to about 280° C., less than or equal to about 270° C., less than or equal to about 260° C., less than or equal to about 250° C., less than or equal to about 240° C., less than or equal to about 230° C., less than or equal to about 220° C., less than or equal to about 210° C., less than or equal to about 200° C., less than or equal to about 190° C., or less than or equal to about 180° C.

The reaction temperature may be greater than or equal to about 230° C., greater than or equal to about 235° C., greater than or equal to about 240° C., greater than or equal to about 245° C., greater than or equal to about 250° C., greater than or equal to about 255° C., greater than or equal to about 260° C., greater than or equal to about 265° C., greater than or equal to about 270° C., greater than or equal to about 275° C., or greater than or equal to about 280° C. The reaction temperature may be less than or equal to about 380° C., less than or equal to about 360° C., less than or equal to about 340° C., less than or equal to about 320° C., less than or equal to about 300° C., or less than or equal to about 290° C.

The reaction time may be selected in consideration of a desired peak emission wavelength, a type of precursor, and the like. The reaction time may be greater than or equal to about 10 minutes, greater than or equal to about 15 minutes, greater than or equal to about 20 minutes, greater than or equal to about 25 minutes, greater than or equal to about 30 minutes, greater than or equal to about 35 minutes, greater than or equal to about 40 minutes, greater than or equal to about 45 minutes, greater than or equal to about 50 minutes, greater than or equal to about 55 minutes, or greater than or equal to about 60 minutes. The reaction time may be less than or equal to about 5 hours, less than or equal to about 4 hours, less than or equal to about 3 hours, less than or equal to about 2 hours, less than or equal to about 1 hour, or less than or equal to about 45 minutes.

The method may further include reacting a metal precursor for shell formation and a non-metal precursor for shell formation in the presence of the semiconductor nanocrystal to form a shell (including a second semiconductor nanocrystal) on the semiconductor nanocrystal. The metal precursor for shell formation and the non-metal precursor for shell formation may be selected in consideration of the composition of the second semiconductor nanocrystal. The metal precursor for shell formation may include a metal powder, an alkylated metal, a metal carboxylate, a metal nitrate, a metal acetylacetonate, a metal halide (a metal chloride, a metal bromide, a metal fluoride, a metal iodide), a metal cyanide, a metal carbonate, a metal peroxide, a metal hydroxide, or a combination thereof. In an embodiment, the metal precursor for shell formation includes a zinc precursor, and the non-metal precursor for shell formation may include a selenium precursor, a sulfur precursor, or a combination thereof. The shell formation reaction temperature is not particularly limited, and the above-described reaction temperature may be referred to. The shell formation reaction time is also not particularly limited and may be appropriately selected in consideration of the type of precursor, shell composition, and shell formation reaction temperature.

The type of a zinc precursor is not particularly limited and may be appropriately selected. For example, the zinc precursor may include zinc metal powder, an alkylated zinc compound, a zinc alkoxide, a zinc carboxylate, zinc nitrate, zinc perchlorate, zinc sulfate, zinc acetylacetonate, a zinc halide, zinc cyanide, zinc hydroxide, zinc oxide, zinc peroxide, or a combination thereof. The zinc precursor may include dimethylzinc, diethylzinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, or a combination thereof. The zinc precursor may include zinc acetate, a zinc carboxylate, an alkylated zinc, or a combination thereof.

The type of the indium precursor is not particularly limited and may be appropriately selected. The indium precursor may be an indium powder, an alkylated indium compound, an indium alkoxide, an indium carboxylate, an indium nitrate, an indium perchlorate, an indium sulfate, an indium acetylacetonate, an indium halide, an indium cyanide, an indium hydroxide, an indium oxide, an indium peroxide, an indium carbonate, or a combination thereof. The indium precursor may include an indium carboxylate such as indium oleate or indium myristate, indium acetate, indium hydroxide, indium chloride, indium bromide, or indium iodide.

The selenium precursor may include a selenium-trioctylphosphine (Se-TOP), a selenium-tributylphosphine (Se-TBP), a selenium-triphenylphosphine (Se-TPP), a selenium-diphenylphosphine (Se-DPP), or a combination thereof, but is not limited thereto.

The organic solvent may include a primary amine compound of C6 to C40 or C5 to C30. The organic solvent may include a primary amine compound containing an aliphatic hydrocarbon group of C6 to C40 (for example, an alkyl group, an alkenyl group, or an alkynyl group) such as hexadecylamine or oleylamine. The amount of the primary amine compound in the organic solvent may be greater than or equal to about 20%, greater than or equal to about 30%, greater than or equal to about 40%, greater than or equal to about 50%, greater than or equal to about 60%, greater than or equal to about 70%, greater than or equal to about 80%, or greater than or equal to about 90%, based on the total volume of the organic solvent. The amount of the primary amine compound in the organic solvent may be less than or equal to about 100%, less than or equal to about 95%, less than or equal to about 85%, less than or equal to about 75%, less than or equal to about 65%, less than or equal to about 55%, less than or equal to about 45%, less than or equal to about 35%, or less than or equal to about 25%, based on the total volume of the organic solvent. In an embodiment, the organic solvent may further include or may not include an additional solvent. The additional solvent may be a secondary amine of C6 to C40 or C8 to C22 such as dioctylamine, a tertiary amine of C6 to C40 or C8 to C22 such as trioctylamine, a nitrogen-containing heterocyclic compound such as pyridine, an aliphatic hydrocarbon such as hexane, heptane, octane, octadecene, hexadecane, octadecane (ODE), or squalane, an aromatic hydrocarbon substituted with a C6 to C30 alkyl group such as phenyldodecane, phenyltetradecane, or phenylhexadecane, a primary, secondary, or tertiary phosphine substituted with at least one (e.g., 1, 2, or 3) C6 to C22 alkyl group (for example, trioctylphosphine), a phosphine oxide substituted with at least one (e.g., 1, 2, or 3) C6 to C22 alkyl group (e.g., trioctylphosphine oxide), an aromatic ether such as phenyl ether or benzyl ether of C12 to C22, or a combination thereof. When present, a volume ratio of the organic solvent to the additional solvent (organic solvent:additional solvent) may be in a range of 1:0.1 to 4.5, 1:0.2 to 4, 1:0.3 to 3, 1:0.4 to 2.5, 1:0.45 to 2, 1:0.5 to 1.8, 1:0.6 to 1.2, 1:0.7 to 1.1, 1:0.8 to 1, 1:0.85 to 0.95, 1:0.9 to 0.93, or a range of a combination thereof.

The organic ligand may coordinate to the surface of the prepared semiconductor nanoparticle so that the semiconductor nanoparticle may be well dispersed in a solution. The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, RHPOOH, R₂POOH or a combination thereof, where R and R′ are each independently a substituted or unsubstituted aliphatic hydrocarbon of greater than or equal to about C1, greater than or equal to about C6, or greater than or equal to about C10 and less than or equal to about C40, less than or equal to about C35, or less than or equal to about C25, or a substituted or unsubstituted aromatic hydrocarbon of C6 to C40, or a combination thereof. The ligand may be used alone or as a mixture of two or more compounds. The reaction solution may further include the organic ligand. In an embodiment, the R and R′ are each independently a substituted or unsubstituted aliphatic hydrocarbon of C1 to C40 (or C3 to C24) (e.g., an alkyl group, an alkenyl group, or an alkynyl group), or a substituted or unsubstituted aromatic hydrocarbon of C6 to C40 (or C6 to C24) (e.g., an aryl group of C6 to C20). Examples of the organic ligand may include methanethiol, ethanethiol, propanethiol, butanethiol, pentanethiol, hexanethiol, heptanethiol, octanethiol, nonanethiol, decanethiol, dodecanethiol, hexadecanethiol, octadecanethiol, benzylthiol; methylamine, ethylamine, propylamine, butylamine, pentylamine, hexylamine, octylamine, dodecylamine, hexadecylamine, octadecylamine, dimethylamine, diethylamine, dipropylamine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid; substituted or unsubstituted methylphosphine (e.g., trimethylphosphine, methyldiphenylphosphine), substituted or unsubstituted ethylphosphine (e.g., triethylphosphine, ethyldiphenylphosphine), substituted or unsubstituted propylphosphine, butylphosphine, pentylphosphine, octylphosphine (e.g., trioctylphosphine (TOP)); substituted or unsubstituted methylphosphine oxide (e.g., trimethylphosphine oxide, methyldiphenylphosphine oxide), ethylphosphine oxide (e.g., triethylphosphine oxide, ethyldiphenylphosphine oxide), propylphosphine oxide, butylphosphine oxide, octylphosphine oxide (e.g., trioctylphosphine oxide (TOPO)); diphenylphosphine, triphenylphosphine compound, or an oxide thereof; phosphonic acid, hexylphosphonic acid, octylphosphonic acid, dodecylphosphonic acid, tetradecylphosphonic acid, hexadecylphosphonic acid, octadecylphosphonic acid, a C5 to C20 alkylphosphonic acid; or a combination thereof.

In an embodiment, the reaction solution or the organic ligand may not include dodecanethiol. The reaction solution or the organic ligand may not include a thiol compound.

After completion of the reaction, a semiconductor nanocrystal or a nanoparticle including the same may be recovered by pouring an excess amount of a non-solvent to remove an extra organic material not coordinated on the surface and subjecting the obtained mixture to centrifugation. For example, after termination of the reaction, when adding a non-solvent to the reaction product, the semiconductor nanoparticle coordinated with the ligand compound may be separated. The non-solvent may be a polar solvent that is miscible with the solvent used in the core formation and/or shell formation reaction but is incapable of dispersing the manufactured nanocrystal. The non-solvent may be determined depending on the solvent used in the reaction, and for example, may include acetone, ethanol, butanol, isopropanol, ethylene glycol, water, tetrahydrofuran (THF), dimethylsulfoxide (DMSO), diethyl ether, formaldehyde, acetaldehyde, ethylene glycol, a solvent having a solubility parameter similar to that of the above-listed solvents, or a combination thereof. The separation may be carried out using centrifugation, precipitation, chromatography, or distillation. The separated nanocrystal may be washed, if necessary, by adding it into a washing solvent. The washing solvent is not particularly limited, and a solvent having a solubility parameter similar to that of the ligand may be used, examples of which include hexane, heptane, octane, chloroform, toluene, and benzene.

The semiconductor nanocrystal or the nanoparticle may be non-dispersible or non-soluble in water, the aforementioned non-solvent, or a combination thereof. The semiconductor nanocrystal or the nanoparticle may be dispersed in the aforementioned organic solvent. In an embodiment, the semiconductor nanocrystal or the nanoparticle may be dispersed in an aliphatic hydrocarbon of C6 to C40, a substituted or unsubstituted aromatic hydrocarbon of C6 to C40, or a combination thereof.

The obtained semiconductor nanocrystal or the nanoparticle including the same (hereinafter, referred to as “semiconductor nanoparticle) may exhibit a property as described herein. The shape of the manufactured semiconductor nanoparticle is not particularly limited and may include, for example, spherical, polyhedral, pyramidal, multipod, or cubic, nanotube, nanowire, nanofiber, nanosheet, or a combination thereof, but is not limited thereto.

The manufactured semiconductor nanoparticle may include an organic ligand and/or an organic solvent on the surface. The organic ligand and/or the organic solvent may be bound to the surface of the semiconductor nanoparticle of an embodiment. The organic ligand and the organic solvent are as described herein.

In an embodiment, a composite includes a matrix and the semiconductor nanoparticle dispersed in the matrix. The composite may further include a metal oxide fine particle. The composite may be configured to emit a first light. The composite may be a patterned film. The first light may be green light. The composite may further include a semiconductor nanoparticle configured to emit a second light different from the first light. The peak emission wavelength for the first light and the second light may be referred to as described herein. The composite may be in a sheet form. The sheet may further include the semiconductor nanoparticle additionally configured to emit the second light different from the first light.

The composite may include the semiconductor nanoparticle or a population thereof (for example, in a predetermined amount). The absorbance of incident light of the composite may be greater than or equal to about 70%, greater than or equal to about 73%, greater than or equal to about 75%, greater than or equal to about 77%, greater than or equal to about 80%, greater than or equal to about 83%, greater than or equal to about 85%, greater than or equal to about 87%, greater than or equal to about 90%, greater than or equal to about 93%, greater than or equal to about 94%, greater than or equal to about 95%, greater than or equal to about 96%, greater than or equal to about 97%, greater than or equal to about 98%, or greater than or equal to about 99%. The absorbance of incident light of the composite may be 70% to 100%, 80% to 98%, 95% to 99%, 96% to 98%, or a combination thereof.

The absorbance of incident light may be defined as follows:

$$Absorbance of incident light = [ ( B - {B}^{′} ) / B ] \times 100 ( \% )$$

B: an amount of incident light provided to the composite
B′: an amount of incident light transmitted through the composite

The photo-conversion efficiency (CE) or internal quantum efficiency (IQE) of the composite obtained by the following formula may be greater than or equal to about 20%, greater than or equal to about 25%, greater than or equal to about 30%, greater than or equal to about 35%, greater than or equal to about 40%, or greater than or equal to about 45%:

Photo-conversion efficiency or internal quantum efficiency (IQE, %)=[A/(B−B′)]×100(%)

$$External quantum efficiency ( EQE , \% ) = [ A / B ] \times 100 ( \% )$$

A: an amount of first light emitted from the composite
B: an amount of incident light provided to the composite
B′: an amount of incident light transmitted through the composite

A composite including the semiconductor nanoparticle of an embodiment may have a process retention rate, according to the following formula, of greater than or equal to about 70%, greater than or equal to about 75%, greater than or equal to about 80%, greater than or equal to about 85%, greater than or equal to about 90%, or greater than or equal to about 100%:

$$Process retention ( \% ) = [ QE 2 / QE 1 ] \times 100$$

In the above formula, QE1 is the (internal or external) quantum efficiency of the composite before heat treatment after polymerization, and QE2 is the (internal or external) quantum efficiency of the composite after heat treatment.

The process retention may be in a range of 10% to 150%, 20% to 130%, 25% to 100%, 30% to 99%, 68% to 95%, 70% to 85%, or a combination thereof.

In an embodiment, the composite may be manufactured from an ink composition. The ink composition may include a liquid vehicle; and semiconductor nanoparticles of an embodiment (e.g., a plurality thereof). The semiconductor nanoparticles may be dispersed in the liquid vehicle. The liquid vehicle may include a liquid monomer, an organic solvent, or a combination thereof. The ink composition may further include, or may substantially not include, a volatile organic solvent. The ink composition may further include metal oxide fine particles (e.g., dispersed in the liquid vehicle). The ink composition may further include a dispersant (for dispersing the semiconductor nanoparticles and/or the metal oxide fine particles). The dispersant may include a carboxylic group-containing organic compound (a monomer or a polymer). The liquid vehicle may not include an organic solvent (e.g., volatile). The ink composition may be a solvent-free system.

The liquid monomer may include a (photo) polymerizable monomer including a carbon-carbon double bond. The composition may optionally further include a (thermal or photo) initiator. The composition may be initiated to polymerize by light or heat. The ink composition may provide the composite through polymerization.

Details of the nanoparticle(s) in the composition (or composite) are as described herein. An amount of the semiconductor nanoparticle in the composition (or composite) may be appropriately adjusted in consideration of a desired end use (e.g., a color filter, or the like). In an embodiment, an amount of the semiconductor nanoparticle in the composition (or composite) may be greater than or equal to about 1 weight percent (wt %), for example, greater than or equal to about 2 wt %, greater than or equal to about 3 wt %, greater than or equal to about 4 wt %, greater than or equal to about 5 wt %, greater than or equal to about 6 wt %, greater than or equal to about 7 wt %, greater than or equal to about 8 wt %, greater than or equal to about 9 wt %, greater than or equal to about 10 wt %, greater than or equal to about 15 wt %, greater than or equal to about 20 wt %, greater than or equal to about 25 wt %, greater than or equal to about 30 wt %, greater than or equal to about 35 wt %, or greater than or equal to about 40 wt % based on the solid content of the composition or composite (hereinafter, the solid content may be a solid content of the composition or a solid content of the composite). The amount of the semiconductor nanoparticle may be less than or equal to about 70 wt %, for example, less than or equal to about 65 wt %, less than or equal to about 60 wt %, less than or equal to about 55 wt %, or less than or equal to about 50 wt %, based on the solid content of the composition or composite. A weight percentage of a given component with respect to a total solid content in a composition may represent an amount of the given component in the composite described herein.

In an embodiment, an ink composition may be a semiconductor nanoparticle-including photoresist composition applicable in a photolithography manner. In an embodiment, an ink composition may be a semiconductor nanoparticle-including composition capable of providing a pattern in a printing manner (e.g., a droplet discharging method such as an inkjet printing). The composition according to an embodiment may not include a conjugated (or conductive) polymer (except for a cardo binder to be described herein). The composition according to an embodiment may include a conjugated polymer. Herein, the conjugated polymer refers to a polymer (e.g., polyphenylenevinylene, or the like) having a conjugated double bond in the main chain.

In the composition according to an embodiment, the dispersant may ensure dispersibility of the nanoparticle (e.g., the semiconductor nanoparticle). In an embodiment, the dispersant may be a binder (or a binder polymer). The binder may include a carboxylic acid group (e.g., in the repeating unit). The binder may be an insulating polymer. The binder may be a carboxylic acid group-including compound (a monomer or a polymer).

In the composition (or the composite), an amount of the dispersant may be greater than or equal to about 0.5 wt %, for example, greater than or equal to about 1 wt %, greater than or equal to about 5 wt %, greater than or equal to about 10 wt %, greater than or equal to about 15 wt %, or greater than or equal to about 20 wt %, based on the total solid content of the composition (or composite). The amount of the dispersant may be less than or equal to about 55 wt %, less than or equal to about 35 wt %, less than or equal to about 33 wt %, or less than or equal to about 30 wt %, based on the total solid content of the composition (or composite).

In the composition (or the liquid vehicle), a liquid monomer or a polymerizable (e.g., photopolymerizable) monomer (hereinafter, referred to as a monomer) including the carbon-carbon double bond may include a (e.g., photopolymerizable) (meth)acryl-including monomer. The monomer may be a precursor for an insulating polymer.

An amount of the (photopolymerizable) monomer, based on a total weight or a total solid content of the composition, may be greater than or equal to about 0.5 wt %, for example, greater than or equal to about 1 wt %, greater than or equal to about 2 wt %, greater than or equal to about 3 wt %, greater than or equal to about 5 wt %, or greater than or equal to about 10 wt %. An amount of the (photopolymerizable) monomer, based on a total weight or a total solid content of the composition, may be less than or equal to about 30 wt %, for example, less than or equal to about 28 wt %, less than or equal to about 25 wt %, less than or equal to about 23 wt %, less than or equal to about 20 wt %, less than or equal to about 18 wt %, less than or equal to about 17 wt %, less than or equal to about 16 wt %, or less than or equal to about 15 wt %.

The (photo) initiator included in the composition may be used for (photo) polymerization of the aforementioned monomer. The initiator is a compound accelerating a radical reaction (e.g., radical polymerization of monomer) by producing radical chemical species under a mild condition (e.g., by heat or light). The initiator may be a thermal initiator or a photoinitiator. The initiator is not particularly limited and may be appropriately selected.

In the composition, an amount of the initiator may be appropriately adjusted considering types and amounts of the polymerizable monomers. In an embodiment, the amount of the initiator may be greater than or equal to about 0.01 wt %, for example, greater than or equal to about 1 wt %, and less than or equal to about 10 wt %, for example, less than or equal to about 9 wt %, less than or equal to about 8 wt %, less than or equal to about 7 wt %, less than or equal to about 6 wt %, or less than or equal to about 5 wt %, based on the total weight (or the total solid content) of the composition, but is not limited thereto.

The composition (or composite) may further include a (multi- or monofunctional) thiol compound having at least one thiol group at the terminal end (or a moiety derived therefrom, such as a moiety produced by a reaction between a thiol and a carbon-carbon double bond, for example, a sulfide group), metal oxide particulate, or a combination thereof.

The metal oxide particulate (e.g., metal oxide nanoparticle) may include TiO₂, SiO₂, BaTiO₃, Ba₂TiO₄, ZnO, or a combination thereof. In the composition (or composite), an amount of the metal oxide particulates may be greater than or equal to about 1 wt %, greater than or equal to about 2 wt %, greater than or equal to about 3 wt %, greater than or equal to about 5 wt %, or greater than or equal to about 10 wt % and less than or equal to about 50 wt %, less than or equal to about 40 wt %, less than or equal to about 30 wt %, less than or equal to about 25 wt %, less than or equal to about 20 wt %, less than or equal to about 15 wt %, less than or equal to about 10 wt %, less than or equal to about 7 wt %, less than or equal to about 5 wt %, or less than or equal to about 3 wt %, based on the total solid content.

A diameter of the metal oxide particulate is not particularly limited, and may be appropriately selected. The diameter of the metal oxide particulates may be greater than or equal to about 100 nm, for example greater than or equal to about 150 nm, or greater than or equal to about 200 nm and less than or equal to about 1000 nm, or less than or equal to about 800 nm.

The polythiol compound may be a dithiol compound, a trithiol compound, a tetrathiol compound, or a combination thereof. For example, the thiol compound may be ethylene glycol bis(3-mercaptopropionate), ethylene glycol dimercapto acetate, trimethylolpropane tris(3-mercaptopropionate), pentaerythritol tetrakis(3-mercaptopropionate), pentaerythritol tetrakis(2-mercaptoacetate), 1,6-hexanedithiol, 1,3-propanedithiol, 1,2-ethanedithiol, polyethylene glycol dithiol including 1 to 10 ethylene glycol repeating units, or a combination thereof.

An amount of the thiol compound (or moieties derived therefrom) may be less than or equal to about 50 wt %, less than or equal to about 40 wt %, less than or equal to about 30 wt %, less than or equal to about 20 wt %, less than or equal to about 10 wt %, less than or equal to about 9 wt %, less than or equal to about 8 wt %, less than or equal to about 7 wt %, less than or equal to about 6 wt %, or less than or equal to about 5 wt %, based on the total solid content. The amount of the thiol compound (or moieties derived therefrom) may be greater than or equal to about 0.1 wt %, for example, greater than or equal to about 0.5 wt %, greater than or equal to about 1 wt %, greater than or equal to about 5 wt %, greater than or equal to about 10 wt %, greater than or equal to about 15 wt %, greater than or equal to about 18 wt %, or greater than or equal to about 20 wt %, based on the total solid content.

The composition or the liquid vehicle may include an organic solvent. In an embodiment, the composition or the liquid vehicle may not include an organic solvent. If present, the type of organic solvent that may be used is not particularly limited. The type and amount of the organic solvent is appropriately determined in consideration of the types and amounts of the aforementioned main components (i.e., nanoparticles, dispersants, polymerizable monomers, initiators, thiol compounds, or the like, if present) and other additives to be described herein. The composition may include a solvent in a residual amount except for a desired amount of the (non-volatile) solid. In an embodiment, examples of the organic solvent may be an ethylene glycols, such as ethylene glycol, diethylene glycol, polyethylene glycol, and the like; a glycol ether solvent, such as ethylene glycol monomethylether, ethylene glycol monoethyl ether, diethylene glycol monomethyl ether, ethylene glycol diethyl ether, diethylene glycol dimethyl ether, or the like; a glycol ether acetate solvent, such as ethylene glycol acetate, ethylene glycol monoethyl ether acetate, diethylene glycol monoethyl ether acetate, diethylene glycol monobutyl ether acetate, or the like; a propylene glycol solvent, such as propylene glycol, or the like; a propylene glycol ether solvent, such as propylene glycol monomethyl ether, propylene glycol monoethyl ether, propylene glycol monopropyl ether, propylene glycol monobutyl ether, propylene glycol dimethyl ether, dipropylene glycol dimethyl ether, propylene glycol diethyl ether, dipropylene glycol diethyl ether, or the like; a propylene glycol ether acetate solvent, such as propylene glycol monomethyl ether acetate, dipropylene glycol monoethyl ether acetate, or the like; an amide solvent, such as N-methylpyrrolidone, dimethyl formamide, dimethyl acetamide, or the like; a ketone solvent, such as methylethylketone (MEK), methylisobutylketone (MIBK), cyclohexanone, or the like; a petroleum solvent, such as toluene, xylene, solvent naphtha, or the like; an ester solvent, such as ethyl acetate, butyl acetate, ethyl lactate, ethyl 3-ethoxy propionate, or the like; an ether solvent, such as diethyl ether, dipropyl ether, dibutyl ether, or the like; chloroform, a C1 to C40 aliphatic hydrocarbon solvent (e.g., alkane, alkene, or alkyne), a halogen (e.g., chloro) substituted C1 to C40 aliphatic hydrocarbon solvent (e.g., dichloroethane, trichloromethane, or the like), a C6 to C40 aromatic hydrocarbon solvent (e.g., toluene, xylene, or the like), a halogen (e.g., chloro) substituted C6 to C40 aromatic hydrocarbon solvent; or a combination thereof.

In addition to the aforementioned components, the composition (or composite) of an embodiment may further include an additive such as a light diffusing agent, a leveling agent, a coupling agent, or a combination thereof. Components (binder, monomer, solvent, additives, thiol compound, cardo binder, or the like) included in the composition of an embodiment may be appropriately selected, and for specific details thereof, for example, US-2017-0052444-A1 may be referred to, which is incorporated herein in its entirety.

In the preparation of the composition according to an embodiment, each of the above-described components may be manufactured sequentially or simultaneously mixed, and the order thereof is not particularly limited.

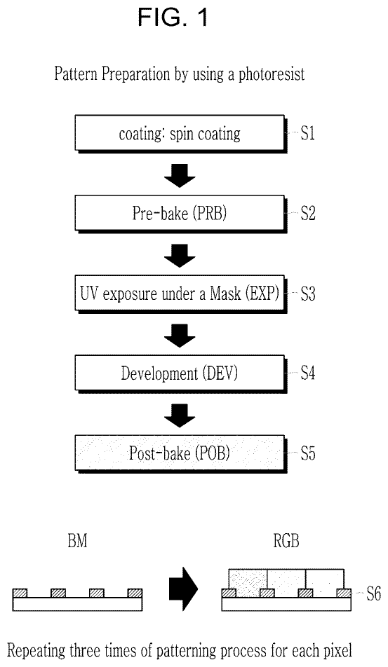

The composition may provide a color conversion layer (or a patterned film of the composite) by (e.g., radical) polymerization. The color conversion layer (or the patterned film of the composite) may be produced using a photoresist composition. Referring to FIG. 1, this method may include forming a film of the aforementioned composition on a substrate (S1); prebaking the film according to selection (S2); exposing a selected region of the film to light (e.g., having a wavelength of less than or equal to about 400 nm) (S3); and developing the exposed film with an alkali developing solution to obtain a pattern of a quantum dot-polymer composite (S4).

Referring to FIG. 1, the aforementioned composition may be applied to a predetermined thickness on a substrate using an appropriate method such as spin coating or slit coating to form a film. The formed film may be optionally subjected to a pre-baking (PRB) step. The pre-baking may be performed by selecting an appropriate condition from known conditions of a temperature, time, an atmosphere, or the like.

The formed (or optionally prebaked) film may be exposed to light having a predetermined wavelength under a mask having a predetermined pattern (EXP). A wavelength and intensity of the light may be selected considering types and amounts of the photoinitiator, types, and amounts of the quantum dots, or the like.

The exposed film may then be treated with an alkali developing solution (e.g., dipping or spraying) to dissolve an unexposed region and obtain a desired pattern (DEV). The obtained pattern may be, optionally, post-exposure baked (POB) to improve crack resistance and solvent resistance of the pattern, for example, at a temperature of about 150° C. to about 230° C. for a predetermined time (e.g., greater than or equal to about 10 minutes, or greater than or equal to about 20 minutes) (S5).

When the color conversion layer or the patterned film of the nanoparticle composite has a plurality of repeating sections (that is, color conversion regions), each repeating section may be formed by preparing a plurality of compositions including quantum dots (e.g., red light emitting quantum dots, green light emitting quantum dots, or optionally, blue light emitting quantum dots) having desired luminous properties (photoluminescence peak wavelength or the like) and repeating the aforementioned pattern-forming process as many times as necessary (e.g., 2 times or more, or 3 times or more) for each composition, resultantly obtaining a nanoparticle-polymer composite having a desired pattern (S6). For example, the nanoparticle-polymer composite may have a pattern of at least two repeating color sections (e.g., RGB color sections). This nanoparticle-polymer composite pattern may be used as a photoluminescence type color filter in a display device.

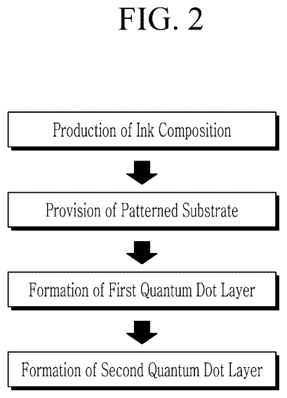

The color conversion layer or patterned film of the semiconductor nanoparticle composite may be produced using an ink composition configured to form a pattern in an inkjet manner. Referring to FIG. 2, such a method may include preparing an ink composition according to an embodiment, providing a substrate (e.g., with pixel areas patterned by electrodes and optionally banks or trench-type partition walls, or the like), and depositing an ink composition on the substrate (or the pixel area) to form, for example, a first composite layer (or first region). The method may include depositing an ink composition on the substrate (or the pixel area) to form, for example, a second composite layer (or second region). The first and second composite layers may be first and second quantum dot layers, respectively. The forming of the first composite layer and forming of the second composite layer may be simultaneously or sequentially performed.

The depositing of the ink composition may be performed using an appropriate liquid crystal discharger, for example an inkjet or nozzle printing system (having an ink storage and at least one print head). The deposited ink composition may provide a (first or second) composite layer through the solvent removal and polymerization by the heating. The method may provide a highly precise nanoparticle-polymer composite film or patterned film for a short time by the simple method.

In the nanoparticle-polymer composite (e.g., first composite) of an embodiment, the (polymer) matrix may include the components described herein with respect to the composition. In the composite, an amount of the matrix, based on a total weight of the composite, may be greater than or equal to about 10 wt %, greater than or equal to about 20 wt %, greater than or equal to about 30 wt %, greater than or equal to about 40 wt %, greater than or equal to about 50 wt %, or greater than or equal to about 60 wt %. The amount of the matrix may be, based on a total weight of the composite, less than or equal to about 95 wt %, less than or equal to about 90 wt %, less than or equal to about 80 wt %, less than or equal to about 70 wt %, less than or equal to about 60 wt %, or less than or equal to about 50 wt %.

The (polymer) matrix may include a dispersant (e.g., a carboxylic acid group-including binder polymer), a polymerization product (e.g., an insulating polymer) of a polymerizable monomer including (at least one, for example, at least two, at least three, at least four, or at least five) carbon-carbon double bonds, a polymerization product of the polymerizable monomer and a polythiol compound having at least two thiol groups (e.g., at a terminal end), or a combination thereof. The matrix may include a linear polymer, a crosslinked polymer, or a combination thereof. The (polymer) matrix may not include a conjugated polymer (excluding cardo resin). The matrix may include a conjugated polymer.

The crosslinked polymer may include a thiol-ene resin, a crosslinked poly(meth)acrylate, a crosslinked polyurethane, a crosslinked epoxy resin, a crosslinked vinyl polymer, a crosslinked silicone resin, or a combination thereof. In an embodiment, the crosslinked polymer may be a polymerization product of the aforementioned polymerizable monomers and optionally a polythiol compound.

The linear polymer may include a repeating unit derived from a carbon-carbon unsaturated bond (e.g., a carbon-carbon double bond). The repeating unit may include a carboxylic acid group. The linear polymer may include an ethylene repeating unit.

The carboxylic acid group-containing repeating unit may include a unit derived from a monomer including a carboxylic acid group and a carbon-carbon double bond, a unit derived from a monomer having a dianhydride moiety, or a combination thereof.

The (polymer) matrix may include a carboxylic acid group-containing compound (e.g., a binder, a binder polymer, or a dispersant) (e.g., for dispersion of nanoparticles or a binder).

The first composite (or a film or pattern thereof) may have, for example, a thickness of less than or equal to about 30 micrometers (μm), less than or equal to about 25 μm, less than or equal to about 20 μm, less than or equal to about 15 μm, less than or equal to about 10 μm, less than or equal to about 8 μm, or less than or equal to about 7 μm to greater than about 2 μm, for example, greater than or equal to about 3 μm, greater than or equal to about 3.5 μm, greater than or equal to about 4 μm, greater than or equal to about 5 μm, greater than or equal to about 6 μm, greater than or equal to about 7 μm, greater than or equal to about 8 μm, greater than or equal to about 9 μm, or greater than or equal to about 10 μm.

The semiconductor nanocrystal described herein or a nanoparticle including the same (hereinafter, referred to as a quantum dot or a semiconductor nanoparticle), a composite (pattern) including the same, or a color conversion panel including the same may be included in an electronic device. Such an electronic device may include a display device, a light emitting diode (LED), an organic light emitting diode (OLED), a quantum dot LED, a sensor, a solar cell, an imaging sensor, a photodetector, or a liquid crystal display device, but embodiments are not limited thereto. The aforementioned quantum dot (or the semiconductor nanoparticle) in an embodiment may be included in an electronic apparatus. Such an electronic apparatus may include, but is not limited to, a virtual reality device, an augmented reality device, a portable terminal device, a monitor, a notebook personal computer (PC), a television, an electric sign board, an electronic display board, a camera, a vehicle (e.g., a car), or the like, but embodiments are not limited thereto. The electronic apparatus may be a portable terminal device, a monitor, a laptop personal computer, or a television including a display device (or a light emitting device) including quantum dots. The electronic apparatus may be a camera or a mobile terminal device including an image sensor including quantum dots. The electronic apparatus may be a camera or a vehicle including a photodetector including quantum dots.

An embodiment provides a color conversion layer (e.g., a color conversion structure or a color conversion panel) including a color conversion region including the semiconductor nanoparticle described herein. The color conversion panel may include a color conversion layer including a color conversion region and optionally a partition wall defining each region of the color conversion layer. The color conversion region may include a first region corresponding to a first pixel, and the first region may include the semiconductor nanoparticles or the semiconductor nanoparticle composite. In the color conversion panel of an embodiment, the semiconductor nanoparticle composite may be in the form of a patterned film. In another embodiment, the semiconductor nanoparticle composite may have a sheet form.

The first region may include a first composite, and the first composite may include a matrix and semiconductor nanoparticles dispersed in the matrix and may be configured to emit first light. An embodiment provides the semiconductor nanoparticles or a population thereof.

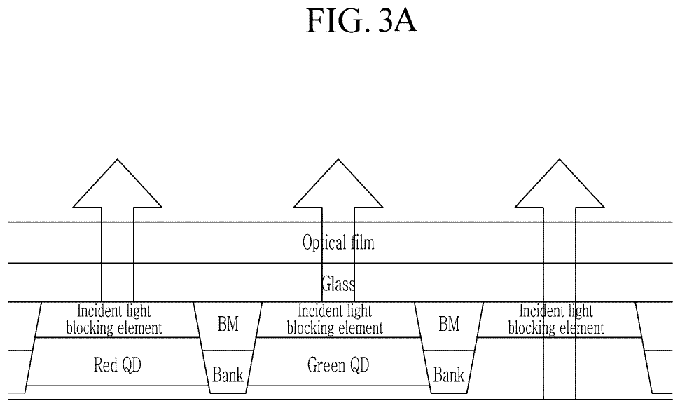

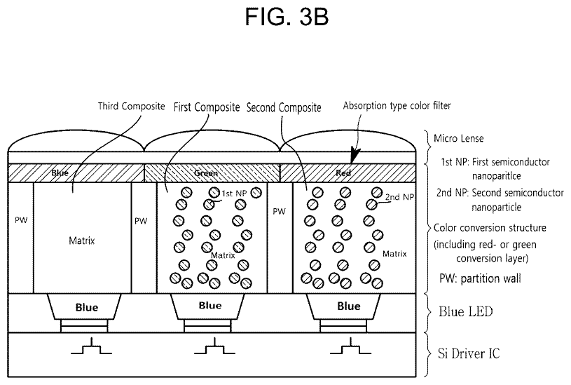

The color conversion layer (e.g., a color conversion structure) may include the semiconductor nanoparticle composite or a patterned film thereof according to an embodiment. FIG. 3A is a schematic cross-sectional view of a color conversion panel according to an embodiment. Referring to FIG. 3A, the color conversion panel may optionally further include a partition wall (e.g., a black matrix (BM), a bank, or a combination thereof) that defines each region of the color conversion layer (e.g., a color conversion structure). FIG. 3B illustrates an electronic device (or a display device) including a color conversion panel and a light source according to another embodiment. In the electronic device of an embodiment, a color conversion panel including a color conversion layer or a color conversion structure may be disposed on an LED on a chip (e.g., a micro LED on a chip). Referring to FIG. 3B, a circuit (e.g., Si driver integrated circuit (IC)) configured to drive the light source may be disposed under a light source (e.g., blue LED) configured to emit incident light (e.g., a blue light). The color conversion layer may include a first composite including a semiconductor nanoparticle emitting a first light (e.g., a green light), and a second composite including a semiconductor nanoparticle emitting a second light (e.g., a red light), or a third composite that emits or passes a third light (e.g., incident light or a blue light). A partition wall (PW) (e.g., including an inorganic material, such as silicon or silicon oxide, or based on an organic material), may be disposed between respective composites. The partition wall may include a trench hole, a via hole, or a combination thereof. A first optical element (e.g., an absorption type color filter) may be disposed on a light extraction surface of a color conversion layer. An additional optical element, such as a micro lens, may be further disposed on the first optical element.

The color conversion region may include a first region configured to emit the aforementioned first light (or green light) (e.g., by irradiation with an incident light). In an embodiment, the first region may correspond to a green pixel. The first region may include a first composite (e.g., a luminescence type composite). The first light may have a peak emission wavelength within a wavelength range to be described later. The first light will be described in more detail for the semiconductor nanoparticles described herein. The peak emission wavelength of the green light may be greater than or equal to about 500 nm, greater than or equal to about 501 nm, greater than or equal to about 504 nm, greater than or equal to about 505 nm, or greater than or equal to about 520 nm. The peak emission wavelength of the green light may be less than or equal to about 580 nm, less than or equal to about 560 nm, less than or equal to about 550 nm, less than or equal to about 530 nm, less than or equal to about 525 nm, less than or equal to about 520 nm, less than or equal to about 515 nm, or less than or equal to about 510 nm.

The color conversion region may further include a (e.g., one or more) second region that is configured to emit a second light (e.g., a red light) different from the first light (e.g., by irradiation with excitation light). The second region may include a second composite. The semiconductor nanoparticle composite in the second region may include a semiconductor nanoparticle (e.g., a quantum dot) being configured to emit a light of a different wavelength (e.g., a different color) from the semiconductor nanoparticle composite disposed in the first region.

The second light may be a red light having a peak emission wavelength of about 600 nm to about 650 nm (e.g., about 620 nm to about 650 nm). The color conversion panel may further include (one or more) third regions that emit or pass a third light (e.g., a blue light) different from the first light and the second light. An incident light may include the third light (e.g., a blue light and optionally a green light). The third light may include a blue light having a peak emission wavelength of greater than or equal to about 380 nm (e.g., greater than or equal to about 440 nm, greater than or equal to about 445 nm, greater than or equal to about 450 nm, or greater than or equal to about 455 nm) to less than or equal to about 480 nm (e.g., less than or equal to about 475 nm, less than or equal to about 470 nm, less than or equal to about 465 nm, or less than or equal to about 460 nm).

In an embodiment, the color conversion panel or the color conversion layer may include a plurality of first regions, and the semiconductor nanoparticle composite may constitute a predetermined pattern to be respectively disposed in the first regions of the color conversion panel. The semiconductor nanoparticle composite (or a pattern thereof) may be prepared from the (ink) composition by any method, for example, in a photolithography manner or in an inkjet printing manner. Accordingly, an embodiment may relate to a composition including a semiconductor nanoparticle, which was described herein in further detail.

In an embodiment, the electronic device or the display device (e.g., display panel) may further include a color conversion layer (or a color conversion panel) and optionally, a light source. The light source may provide incident light to the color conversion layer or the color conversion panel. In an embodiment, the display panel may include a light emitting panel (or a light source), the aforementioned color conversion panel, and a light transmitting layer located between the aforementioned light emitting panel and the aforementioned color conversion panel. The color conversion panel may include a substrate, and the color conversion layer may be disposed on the substrate.

When present, the light source or the light emitting panel may provide an incident light to the color conversion layer or the color conversion panel. The incident light may have a peak emission wavelength of greater than or equal to about 440 nm, for example, greater than or equal to about 450 nm, and less than or equal to about 580 nm, for example, less than or equal to about 480 nm, less than or equal to about 470 nm, or less than or equal to about 460 nm.

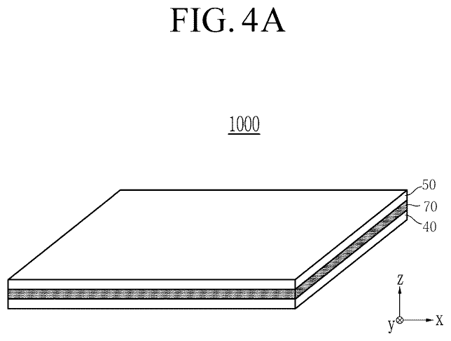

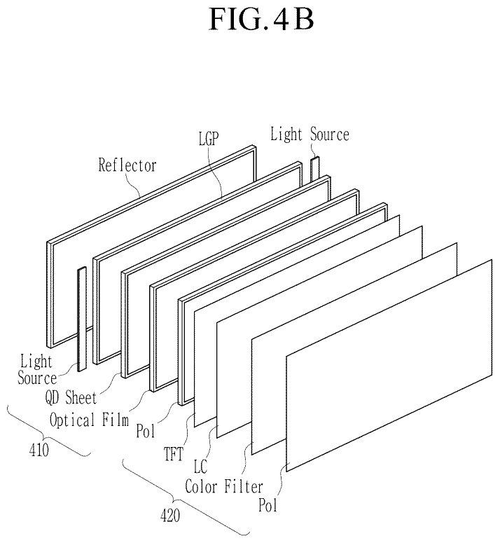

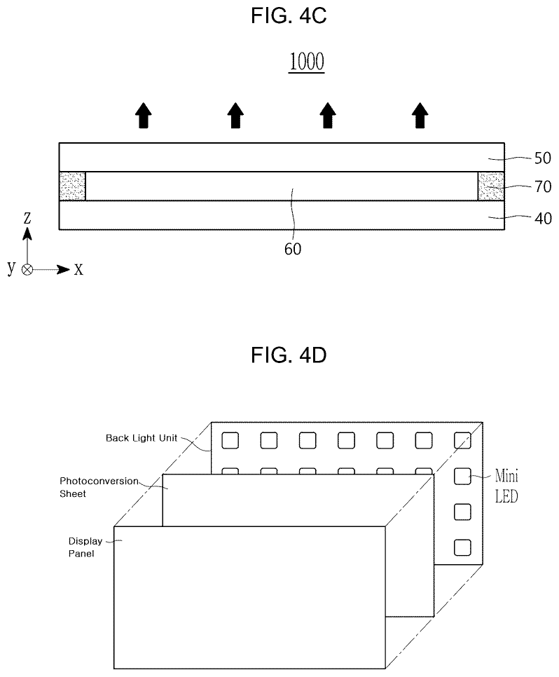

In an embodiment, the electronic device (e.g., a photoluminescent device) may further include a sheet of the nanoparticle composite. Referring to FIG. 4B, the device 400 may include a backlight unit 410 and a liquid crystal panel 420, optionally wherein the backlight unit 410 may include a quantum dot polymer composite sheet (QD sheet). For example, the backlight unit 410 may have a structure that a reflector, a light guide plate (LGP), a light source (a blue LED or the like), the quantum dot polymer composite sheet (QD sheet), and an optical film (a prism, a double brightness enhance film (DBEF, or the like) may be stacked. The liquid crystal panel 420 may be disposed on the backlight unit 410 and have a structure where a thin film transistor (TFT), liquid crystals (LC), and a color filter are included between two polarizers (Pol). The quantum dot polymer composite sheet (QD sheet) may include semiconductor nanoparticles (e.g., quantum dots) emitting a red light and a green light after absorbing light from the light source. A blue light provided from the light source may be combined with the red light and the green light emitted from the respective semiconductor nanoparticles, while passing the quantum dot polymer composite sheet, and converted into a white light. The white light may be separated into a blue light, a green light, and a red light by a color filter in the liquid crystal panel, and then emitted to the outside for each pixel. Referring to FIG. 4D, the backlight unit (BLU) may be a direct type of a BLU without a light guide plate, and may include a plurality of LEDs (e.g., mini LEDs) and a photoconversion sheet or a QD sheet may be disposed on the BLU.

The color conversion panel may include a substrate, and the color conversion layer may be disposed on the substrate. The color conversion layer or the color conversion panel may include a patterned film of the nanoparticle composite. The patterned film may include a repeating section that is configured to emit light of a desired wavelength. The repeating section may include a second region. The second region may be a red light-emitting section. The repeating section may include a first region. The first region may be a green light-emitting section. The repeating section may include a third region. The third region may include a section that emits or transmits a blue light. Details of the first, second, and third regions are as described herein.

The light emitting panel or the light source may be an element emitting an incident light (e.g., an excitation light). The incident light may include a blue light, and, optionally, a green light. The light source may include an LED. The light source may include an organic LED (OLED). The light source may include a micro LED. On the front surface (light emitting surface) of the first region and the second region, an optical element to block (e.g., reflect or absorb) a blue light (and optionally a green light) for example, a blue light (and optionally a green light) blocking layer or a first optical filter that will be described herein may be disposed. In an embodiment, the light source may include an organic light emitting diode to emit a blue light and an organic light emitting diode to emit a green light, and a green light removing filter may be further disposed on a third region through which a blue light is transmitted.

The light emitting panel or the light source may include a plurality of light emitting units respectively corresponding to the first region and the second region, and the light emitting units may include a first electrode and a second electrode facing each other, and an (organic) electroluminescent layer located between the first electrode and the second electrode. The electroluminescent layer may include an organic light emitting material. For example, each light emitting unit of the light source may include an electroluminescent device (e.g., an organic light emitting diode (OLED)) structured to emit light of a predetermined wavelength (e.g., a blue light, a green light, or a combination thereof). Structures and materials of the electroluminescent device and the organic light emitting diode (OLED) are not particularly limited.

Hereinafter, the display panel and the color conversion panel will be described in further detail with reference to the drawings.

Referring to FIGS. 4A and 4C, the display panel 1000 according to an embodiment may include a light emitting panel 40 and a color conversion panel 50. The display panel or the electronic device may further include a light transmitting layer 60 disposed between the light emitting panel 40 and the color conversion panel 50, and a binding material 70 binding the light emitting panel 40 and the color conversion panel 50. The light transmitting layer may include a passivation layer, a filling material, an encapsulation layer, or a combination thereof (not shown). A material for the light transmitting layer may be appropriately selected without particular limitation. The material for the light transmitting layer may be an inorganic material, an organic material, an organic/inorganic hybrid material, or a combination thereof.

The light emitting panel 40 and the color conversion panel 50 each may have a surface opposite the other, i.e., the two respective panels may face each other, with the light transmitting layer (or the light transmitting panel) 60 disposed between the two panels. The color conversion panel 50 may be disposed in a direction such that for example, light emitting from the light emitting panel 40 may irradiate the light transmitting layer 60. The binding material 70 may be disposed along edges of the light emitting panel 40 and the color conversion panel 50, and may be, for example, a sealing material.

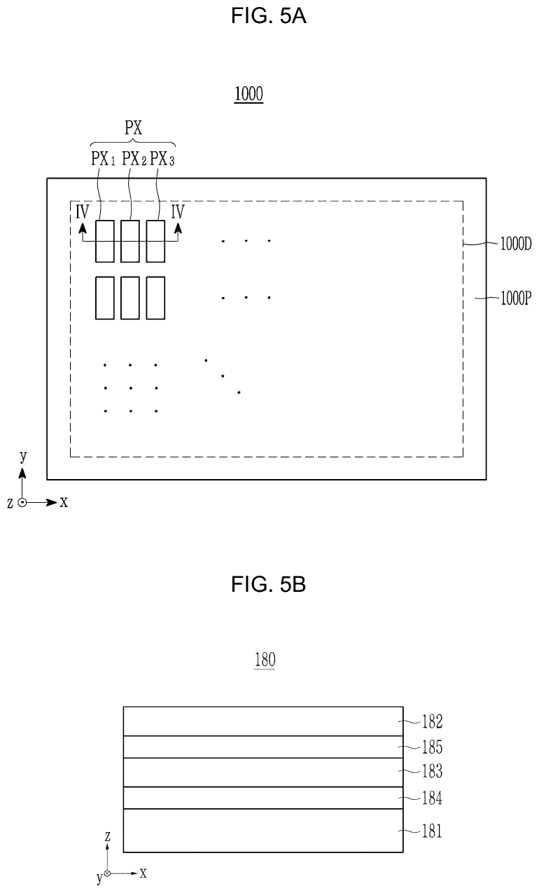

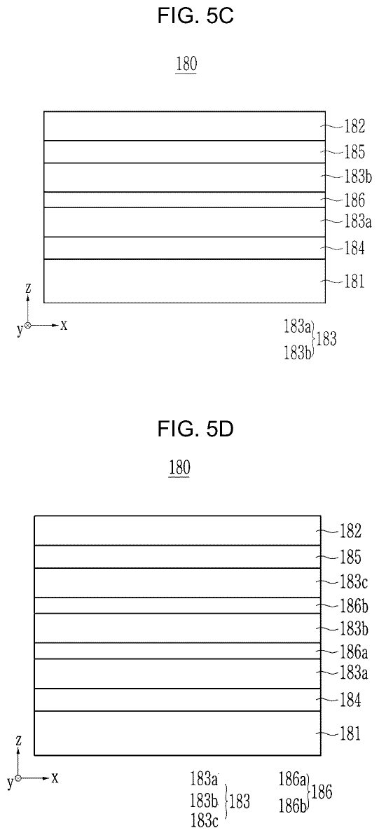

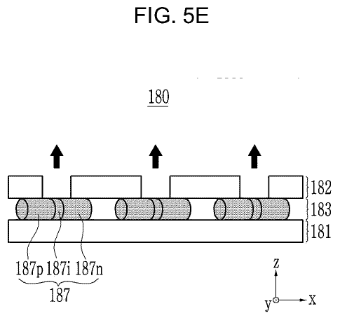

FIG. 5A is a plan view of an embodiment of a pixel arrangement of a display panel. Referring to FIG. 5A, the display panel 1000 may include a display area 1000D displaying an image and a non-display area 1000P positioned in a peripheral area of the display area 1000D and disposed with a binding material.

The display area 1000D may include a plurality of pixels PX arranged along a row (e.g., an x direction), and a column (e.g., a y direction), and each representative pixel PX may include a plurality of sub-pixels PX1, PX2, and PX3 expressing, e.g., displaying, different colors from each other. An embodiment may be idealized with a structure in which three sub-pixels PX1, PX2, and PX3 are configured to provide a pixel. An embodiment may further include an additional sub-pixel, such as a white sub-pixel, and may further include, e.g., at least one, sub-pixel expressing, e.g., displaying the same colors. The plurality of pixels PX may be aligned, for example, in a Bayer matrix, a matrix sold under the trade designation PenTile, a diamond matrix, or the like, or a combination thereof.

The sub-pixels PX1, PX2, and PX3 may express, e.g., display, three primary colors or a color of a combination of three primary colors, for example, may express, e.g., display, a color of red, green, blue, or a combination thereof. For example, the first sub-pixel PX1 may express, e.g., display, a red color, and the second sub-pixel PX2 may express, e.g., display, a green color, and the third sub-pixel PX3 may express, e.g., display, a blue color.

In the drawing, all sub-pixels are idealized to have the same size, but these are not limited thereto, and at least one of the sub-pixels may be larger or smaller than other sub-pixels. In the drawing, all sub-pixels are idealized to have the same shape, but it is not limited thereto and at least one of the sub-pixels may have different shape from the other sub-pixels.

In the display panel or electronic device according to an embodiment, the light emitting panel may include a substrate and a TFT (e.g., an oxide-containing TFT, or the like) disposed on the substrate. A light emitting device (e.g., having a tandem structure, or the like) may be disposed on the TFT.

The light emitting device may include a light emitting layer (e.g., a blue light emitting layer, a green light emitting layer, or a combination thereof) located between the first electrode and the second electrode facing each other. A charge generation layer may be disposed between each of the light emitting layers. Each of the first electrode and the second electrode may be patterned with a plurality of electrode elements to correspond to the pixel. The first electrode may be an anode or a cathode. The second electrode may be a cathode or an anode.

The light emitting device may include an organic LED, a nanorod LED, a mini LED, a micro LED, or a combination thereof.

FIGS. 5B to 5E are cross-sectional views showing light emitting devices of an embodiment, respectively. In an embodiment, “a mini LED” may have a size of greater than or equal to about 100 micrometers, greater than or equal to about 150 micrometers, or greater than or equal to about 200 micrometers and less than or equal to about 1 millimeter, less than or equal to about 0.5 millimeters, less than or equal to about 0.15 millimeters, or less than or equal to about 0.12 millimeters, but is not limited thereto. In an embodiment, “a micro LED” may have a size of less than about 100 micrometers, less than or equal to about 50 micrometers, or less than or equal to about 10 micrometers. The size of the micro LED may be greater than or equal to about 0.1 micrometers, greater than or equal to about 0.5 micrometers, greater than or equal to about 1 micrometer, or greater than or equal to about 5 micrometers, but is not limited thereto.

Referring to FIG. 5B, the light emitting device 180 may include a first electrode 181 and a second electrode 182 facing each other; a light emitting layer 183 located between the first electrode 181 and the second electrode 182; and optionally auxiliary layers 184 and 185 located between the first electrode 181 and the light emitting layer 183, and located between the second electrode 182 and the light emitting layer 183, respectively.

The first electrode 181 and the second electrode 182 may be disposed to face each other along a thickness direction (for example, a z direction), and any one of the first electrode 181 and the second electrode 182 may be an anode and the other may be a cathode. The first electrode 181 may be a light transmitting electrode, a semi-transparent electrode, or a reflective electrode, and the second electrode 182 may be a light transmitting electrode or a semi-transparent electrode. The light transmitting electrode or semi-transparent electrode may be, for example, made of a thin single layer or multiple layers of a metal thin film including conductive metal oxides, such as indium tin oxide (ITO), indium zinc oxide (IZO), zinc oxide (ZnO), tin oxide (SnO), aluminum tin oxide (AITO), fluorine-doped tin oxide (FTO), or the like; or silver (Ag), copper (Cu), aluminum (Al), magnesium (Mg), magnesium-silver (Mg—Ag), magnesium-aluminum (Mg—Al), or a combination thereof. The reflective electrode may include a metal, a metal nitride, or a combination thereof, for example, silver (Ag), copper (Cu), aluminum (Al), gold (Au), titanium (Ti), chromium (Cr), nickel (Ni), an alloy thereof, a nitride thereof (e.g., TiN), or a combination thereof, but embodiments are not limited thereto.

The light emitting layer(s) 183 may include a first light emitting body emitting light with a blue emission spectrum, a second light emitting body emitting light with a green emission spectrum, or a combination thereof.

The blue emission spectrum may have a peak emission wavelength in a wavelength region of greater than or equal to about 400 nm to less than about 500 nm and within the range, in a wavelength region of about 410 nm to about 490 nm, about 420 nm to about 480 nm, about 430 nm to about 470 nm, about 440 nm to about 465 nm, about 445 nm to about 460 nm, or about 450 nm to about 458 nm.

The green emission spectrum may have a peak emission wavelength in a wavelength region of greater than or equal to about 500 nm to less than about 590 nm and within the range, in a wavelength region of about 510 nm to about 580 nm, about 515 nm to about 570 nm, about 520 nm to about 560 nm, about 525 nm to about 555 nm, about 530 nm to about 550 nm, or about 535 nm to about 545 nm.

For example, the light emitting layers 183 or the light emitting body included therein may include a phosphorescent material, a fluorescent material, or a combination thereof. For example, the light emitting body may include an organic light emitting body, wherein the organic light emitting body may be a low molecular compound, a polymer compound, or a combination thereof. Specific types of the phosphorescent material and the fluorescent material are not particularly limited but may be appropriately selected from known materials. For example, the light emitting body may include an inorganic light emitting body, and the inorganic light emitting body may be an inorganic semiconductor, a quantum dot, a perovskite, or a combination thereof. The inorganic semiconductor may include metal nitride, metal oxide, or a combination thereof. The metal nitride, the metal oxide, or the combination thereof may include a Group III metal, such as aluminum, gallium, indium, thallium, or the like, a Group IV metal such as silicon, germanium, tin, or a combination thereof. In an embodiment, the light emitting body may include an inorganic light emitting body, and the light emitting device 180 may be a quantum dot light emitting diode, a perovskite light emitting diode, or a micro light emitting diode (μLED). Materials usable as the inorganic light emitting body may be selected appropriately.

In an embodiment, the light emitting device 180 may further include an auxiliary layer 184 and 185. The auxiliary layer 184 and 185 may be disposed between a first electrode 181 and a light emitting layer 183, and between a second electrode 182 and a light emitting layer 183, respectively. The auxiliary layer 184 and 185 may be a charge auxiliary layer for controlling injection and/or mobility of charges. The auxiliary layers 184 and 185 may include at least one layer or two layers, and for example, may include a hole injection layer, a hole transport layer, an electron blocking layer, an electron injection layer, an electron transport layer, a hole blocking layer, or a combination thereof. At least one of the auxiliary layers 184 and 185 may be omitted, if desired. The auxiliary layer may be formed of a material appropriately selected from materials known for an organic electroluminescent device, or the like.

The light emitting devices 180 disposed in each of the subpixels PX1, PX2, and PX3 may be the same or different from each other. The light emitting devices 180 in each of the subpixels PX1, PX2, and PX3 may emit a light having the same or different emission spectra. The light emitting devices 180 in each of the subpixels PX1, PX2, and PX3 may emit, for example, light having a blue emission spectrum, light having a green emission spectrum, or a combination thereof. The light emitting devices 180 in each of the subpixels PX1, PX2, and PX3 may be separated by a pixel defining layer (not shown).

Referring to FIG. 5C, the light emitting device 180 may be a light emitting device having a tandem structure, and may include a first electrode 181 and a second electrode 182 facing each other; a first light emitting layer 183a and a second light emitting layer 183b located between the first electrode 181 and the second electrode 182; a charge generation layer 186 located between the first light emitting layer 183a and the second light emitting layer 183b; and optionally auxiliary layers 184 and/or 185 located between the first electrode 181 and the first light emitting layer 183a, and/or between the second electrode 182 and the second light emitting layer 183b, respectively.

Details of the first electrode 181, the second electrode 182, and the auxiliary layers 184 and 185 are as described herein.

The first light emitting layer 183a and the second light emitting layer 183b may emit a light having the same or different emission spectra. In an embodiment, the first light emitting layer 183a or the second light emitting layer 183b may emit light having a blue emission spectrum or light having a green emission spectrum, respectively. The charge generation layer 186 may inject an electric charge into the first light emitting layer 183a and/or the second light emitting layer 183b, and may control a charge balance between the first light emitting layer 183a and the second light emitting layer 183b. The charge generation layer 186 may include, for example, an n-type layer and a p-type layer, and may include, for example, an electron transport material and/or a hole transport material including an n-type dopant and/or a p-type dopant. The charge generation layer 186 may include one layer or two or more layers.

Referring to FIG. 5D, a light emitting device (having a tandem structure) may include a first electrode 181 and a second electrode 182 facing each other; a first light emitting layer 183a, a second light emitting layer 183b, and a third light emitting layer 183c located between the first electrode 181 and the second electrode 182; a first charge generation layer 186a located between the first light emitting layer 183a and the second light emitting layer 183b; a second charge generation layer 186b located between the second light emitting layer 183b and the third light emitting layer 183c; and optionally, auxiliary layers 184 and/or 185 located between the first electrode 181 and the first light emitting layer 183a, and/or between the second electrode 182 and the third light emitting layer 183c, respectively.

Details of the first electrode 181, the second electrode 182, and the auxiliary layers 184 and 185 are as described herein.

The first light emitting layer 183a, the second light emitting layer 183b, and the third light emitting layer 183c may emit a light having the same or different emission spectra. The first light emitting layer 183a, the second light emitting layer 183b, and the third light emitting layer 183c may emit a blue light. In an embodiment, the first light emitting layer 183a and the third light emitting layer 183c may emit light of a blue emission spectrum, and the second light emitting layer 183b may emit light of a green emission spectrum. In another embodiment, the first light emitting layer 183a and the third light emitting layer 183c may emit light of a green emission spectrum, and the second light emitting layer 183b may emit light of a blue emission spectrum.

The first charge generation layer 186a may inject an electric charge into the first light emitting layer 183a and/or the second light emitting layer 183b and may control charge balances between the first light emitting layer 183a and the second light emitting layer 183b. The second charge generation layer 186b may inject an electric charge into the second light emitting layer 183b and/or the third light emitting layer 183c and may control charge balances between the second light emitting layer 183b and the third light emitting layer 183c. Each of the first and second charge generation layers 186a and 186b may include one layer or two or more layers, respectively.

Referring to FIG. 5E, in an embodiment, the light emitting device 180 may include a light emitting layer 183, a first electrode 181, a second electrode 182, and a plurality of nanostructures 187 arranged in the light emitting layer 183.

One of the first electrode 181 and the second electrode 182 may be an anode and the other may be a cathode. The first electrode 181 and the second electrode 182 may be an electrode patterned according to a direction of an arrangement of the plurality of nanostructures 187, and may include, for example, a conductive oxide such as indium tin oxide (ITO), indium zinc oxide (IZO), zinc oxide (ZnO), tin oxide (SnO), aluminum tin oxide (AlTO), fluorine-doped tin oxide (FTO), or the like; or silver (Ag), copper (Cu), aluminum (Al), gold (Au), titanium (Ti), chromium (Cr), nickel (Ni), an alloy thereof, a nitride thereof (e.g., TiN); or a combination thereof, but embodiments are not limited thereto.

The light emitting layer 183 may include a plurality of nanostructures 187, and each of the subpixels PX1, PX2, and PX3 may include a plurality of nanostructures 187. In an embodiment, the plurality of nanostructures 187 may be arranged in one direction, but embodiments are not limited thereto. The nanostructures 187 may be a compound-containing semiconductor that is configured to emit light of a predetermined wavelength for example with an application of an electric current, and may be, for example, a linear nanostructure, such as a nanorod or a nanoneedle. A diameter or a long diameter of the nanostructures 187 may be, for example, several nanometers to several hundreds of nanometers, and aspect ratios of the nanostructures 187 may be greater than about 1, greater than or equal to about 1.5, greater than or equal to about 2.0, greater than or equal to about 3.0, greater than or equal to about 4.0, greater than or equal to about 4.5 or greater than or equal to about 5.0 to less than or equal to about 20, for example, greater than about 1 to about 20, greater than or equal to about 1.5 to about 20, greater than or equal to about 2.0 to about 20, greater than or equal to about 3.0 to about 20, greater than or equal to about 4.0 to about 20, greater than or equal to about 4.5 to about 20, or greater than or equal to about 5.0 to about 20.

Each of the nanostructures 187 may include a p-type region 187p, an n-type region 187n, and a multiple quantum well region 187i, and may be configured to emit light from the multiple quantum well region 187i. The nanostructure 187 may include, for example, gallium nitride (GaN), indium gallium nitride (InGaN), aluminum gallium nitride (AlGaN), or a combination thereof, and may have, for example, a core-shell structure.

The plurality of nanostructures 187 may emit light having the same or different emission spectra. In an embodiment, the nanostructure may emit light of a blue emission spectrum, for example, light of a blue emission spectrum having a peak emission wavelength in a wavelength region of greater than or equal to about 400 nm to less than 500 nm, about 410 nm to about 490 nm, or about 420 nm to about 480 nm.

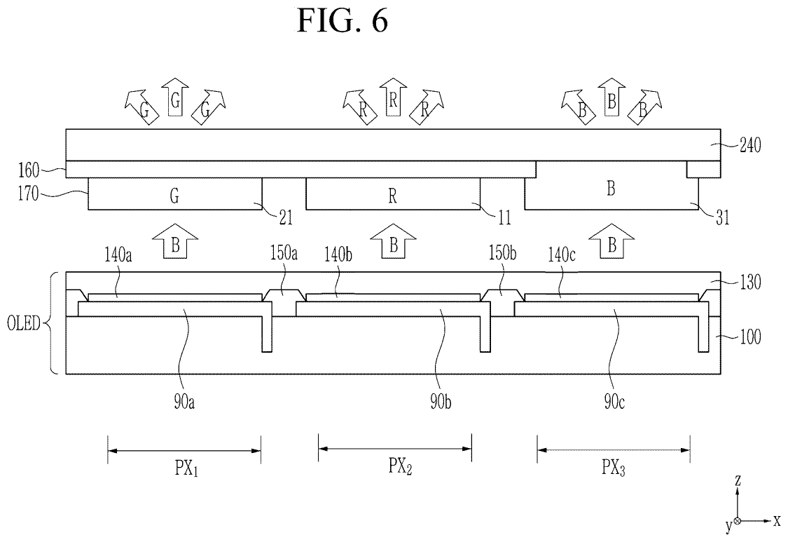

FIG. 6 is a schematic cross-sectional view of a device (or a display panel) according to an embodiment. Referring to FIG. 6, the light source (or the light emitting panel) may include an organic light emitting diode that emits a blue light (B) (and optionally a green light (G)). The organic light emitting diode (OLED) may include at least two pixel electrodes 90a, 90b, 90c formed on the substrate 100, pixel defining layers 150a, 150b formed between the adjacent pixel electrodes 90a, 90b, 90c, organic light emitting layers 140a, 140b, 140c formed on each pixel electrode 90a, 90b, 90c, and a common electrode layer 130 formed on the organic light emitting layer 140a, 140b, 140c. A thin film transistor (TFT) and a substrate may be disposed under the organic light emitting diode (OLED), which are not shown. Pixel areas of the OLED may be disposed corresponding to the first, second, and third regions described herein. In an embodiment, the color conversion panel and the light emitting panel may be separated as shown in FIG. 6. In an embodiment, the color conversion panel may be stacked directly on the light emitting panel.

A laminated structure including the semiconductor nanoparticle composite pattern 170 (e.g., a first region 11 or R including red light emitting semiconductor nanoparticle, a second region 21 or G including green light emitting semiconductor nanoparticle, and a third region 31 or B including or not including a semiconductor nanoparticle, e.g., a blue light emitting semiconductor nanoparticle) and the substrate 240 may be disposed on the light source. The blue light emitted from the light source may enter the first region and second region and may emit a red light and a green light, respectively. The blue light emitted from the light source may pass through the third region. An element (first optical filter 160 or excitation light blocking layer) configured to block the excitation light may be disposed between the semiconductor nanoparticle composite layers R and G and the substrate, if desired. In an embodiment, the excitation light may include a blue light and a green light, and a green light blocking filter (not shown) may be added to the third region. The first optical filter or the excitation light blocking layer will be described in more detail herein.

Such a (display) device may be produced by separately producing the aforementioned laminated structure and LED or OLED (e.g., emitting a blue light) and then combining the laminated structure and LED or OLED. The (display) device may be produced by directly forming the semiconductor nanoparticle composite pattern on the LED or OLED.

In the color conversion panel or a display device, a substrate may be a substrate including an insulation material. The substrate may include glass; a polymer, such as a polyester of poly(ethylene terephthalate) (PET), poly(ethylene naphthalate) (PEN), or the like, a polycarbonate, or a polyacrylate; a polysiloxane (e.g. polydimethylsiloxane (PDMS), or the like); an inorganic material such as Al₂O₃, ZnO, or the like; or a combination thereof, but embodiments are not limited thereto. A thickness of the substrate may be appropriately selected taking into consideration a substrate material but is not particularly limited. The substrate may have flexibility. The substrate may have a transmittance of greater than or equal to about 50%, greater than or equal to about 60%, greater than or equal to about 70%, greater than or equal to about 80%, or greater than or equal to about 90% for light emitted from the semiconductor nanoparticle.

A wire layer including a thin film transistor or the like may be formed on the substrate. The wire layer may further include a gate line, a sustain voltage line, a gate insulating film, a data line, a source electrode, a drain electrode, a semiconductor layer, a protective layer, or the like. The detailed structure of the wire layer may vary depending on an embodiment. The gate line and the sustain voltage line may be electrically separated from each other, and the data line may be insulated, crossing the gate line and the sustain voltage line. The gate electrode, the source electrode, and the drain electrode may form a control terminal, an input terminal, and an output terminal of the thin film transistor, respectively. The drain electrode may be electrically connected to the pixel electrode that will be described herein.

The pixel electrode may function as an electrode (e.g., anode) of the display device. The pixel electrode may be formed of a transparent conductive material, such as indium tin oxide (ITO) or indium zinc oxide (IZO). The pixel electrode may be formed of a material having a light blocking property, such as gold (Au), platinum (Pt), nickel (Ni), tungsten (W), chromium (Cr), molybdenum (Mo), iron (Fe), cobalt (Co), copper (Cu), palladium (Pd), or titanium (Ti). The pixel electrode may have a two-layered structure where the transparent conductive material and the material having light blocking properties are stacked sequentially.

Between two adjacent pixel electrodes, a pixel define layer (PDL) may overlap with a terminal end of the pixel electrode to divide the pixel electrode into a pixel unit. The pixel define layer is an insulating layer which may electrically block the at least two pixel electrodes.

The pixel define layer may cover a portion of the upper surface of the pixel electrode, and the remaining region of the pixel electrode where it is not covered by the pixel define layer may provide an opening. An organic light emitting layer that will be described herein may be formed on the region defined by the opening.

The organic light emitting layer may define each pixel area by the aforementioned pixel electrode and the pixel define layer. In other words, one pixel area may be defined as an area where it is formed with one organic light emitting unit layer which is contacted with one pixel electrode divided by the pixel define layer. In the display device according to an embodiment, the organic light emitting layer may be defined as a first pixel area, a second pixel area, and a third pixel area, and each pixel area may be spaced apart from each other leaving a predetermined interval by the pixel define layer.

In an embodiment, the organic light emitting layer may emit a third light belonging to a visible light region or belonging to an ultraviolet (UV) region. Each of the first to the third pixel areas of the organic light emitting layer may emit a third light. In an embodiment, the third light may be a light having a higher energy in a visible light region, and for example, may be a blue light (and optionally a green light). In an embodiment, all pixel areas of the organic light emitting layer may be designed to emit the same light, and each pixel area of the organic light emitting layer may be formed of materials that are the same or similar or may show the same or similar properties. Thus, a process of forming the organic light emitting layer may be simplified, and the display device may be easily applied for, e.g., made by, a large scale/large area process. However, the organic light emitting layer according to an embodiment is not necessarily limited thereto, but the organic light emitting layer may be designed to emit at least two different lights, e.g., at least two different colored lights.

The organic light emitting layer may include an organic light emitting unit layer in each pixel area, and each organic light emitting unit layer may further include an auxiliary layer (e.g., a hole injection layer, a hole transport layer, an electron transport layer, or the like) besides the light emitting layer.

The common electrode may function as a cathode of the display device. The common electrode may be formed of a transparent conductive material, such as indium tin oxide (ITO) or indium zinc oxide (IZO). The common electrode may be formed on the organic light emitting layer and may be integrated therewith.

A planarization layer or a passivation layer (not shown) may be formed on the common electrode. The planarization layer may include a (e.g., transparent) insulating material for ensuring electrical insulation with the common electrode.

In an embodiment, the display device may further include a lower substrate, a polarizing plate disposed under the lower substrate, and a liquid crystal layer disposed between the laminated structure and the lower substrate, and in the laminated structure, the photoluminescence layer (i.e., light emitting layer) may be disposed to face the liquid crystal layer. The display device may further include a polarizing plate located between the liquid crystal layer and the light emitting layer. The light source may further include LED, and, if desired, a light guide plate.

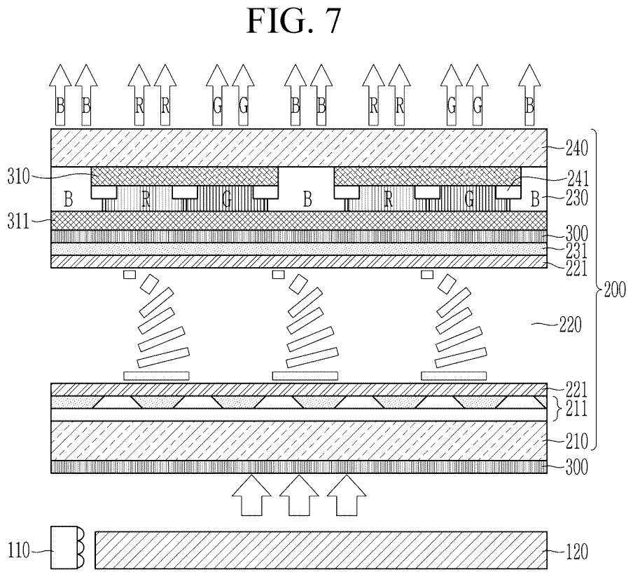

In an embodiment, the display device (e.g., a liquid crystal display device) are illustrated with a reference to a drawing. FIG. 7 is a schematic cross-sectional view showing a liquid crystal display device according to an embodiment. Referring to FIG. 7, the display device of an embodiment may include a liquid crystal panel 200, a polarizing plate 300 disposed under the liquid crystal panel 200, and a backlight unit disposed under the polarizing plate 300.

The liquid crystal panel 200 may include a lower substrate 210, a stacked structure, and a liquid crystal layer 220 disposed between the stack structure and the lower substrate. The stack structure may include a transparent substrate 240, a first optical filter layer 310, a photoluminescent layer 230 including a pattern of a semiconductor nanoparticle polymer composite, and a second optical filter layer 311.

The lower substrate 210, also referred to as an array substrate, may be a transparent insulating material substrate. The substrate may be as described herein. A wire plate 211 may be provided on an upper surface of the lower substrate 210. The wire plate 211 may include a plurality of gate wires (not shown) and data wires (not shown) that define a pixel area, a thin film transistor disposed adjacent to a crossing region of gate wires and data wires, and a pixel electrode for each pixel area, but embodiments are not limited thereto. Details of such a wire plate are not particularly limited.

A liquid crystal layer 220 may be provided on the wire plate 211. The liquid crystal panel 200 may include an alignment layer 221 on and under the liquid crystal layer 220 to initially align the liquid crystal material included therein. Details (e.g., a liquid crystal material, an alignment layer material, a method of forming liquid crystal layer, a thickness of liquid crystal layer, or the like) of the liquid crystal layer and the alignment layer are not particularly limited.

A lower polarizing plate 300 may be provided under the lower substrate. Materials and structures of the polarizing plate 300 are not particularly limited. A backlight unit (e.g., emitting a blue light) may be disposed under the polarizing plate 300. An upper optical element or the polarizing plate 300 may be provided between the liquid crystal layer 220 and the transparent substrate 240, but is not limited thereto. For example, the upper polarizing plate may be disposed between the liquid crystal layer 220 and the photoluminescent layer 230. The polarizing plate may be any polarizer that can be used in a liquid crystal display device. The polarizing plate may be triacetyl cellulose (TAC) having a thickness of less than or equal to about 200 μm, but is not limited thereto. In another embodiment, the upper optical element may be a coating that controls a refractive index without a polarization function.

The backlight unit may include a light source 110. The light source may emit a blue light or a white light. The light source may include, but is not limited to, a blue LED, a white LED, a white OLED, or a combination thereof.

The backlight unit may further include a light guide plate 120. In an embodiment, the backlight unit may be of an edge type. For example, the backlight unit may include a reflector (not shown), a light guide plate (not shown) provided on the reflector and providing a planar light source to the liquid crystal panel 200, and/or at least one optical sheet (not shown) on the light guide plate, for example, a diffusion plate, a prism sheet, and the like, but the present disclosure is not limited thereto. The backlight unit may not include a light guide plate. In an embodiment, the backlight unit may be direct lighting. For example, the backlight unit may have a reflector (not shown) and a plurality of fluorescent lamps on the reflector at regular intervals, or may have an LED operating substrate on which a plurality of light emitting diodes, a diffusion plate thereon, and optionally at least one optical sheet may be disposed. Details (e.g., each component of a light emitting diode, a fluorescent lamp, a light guide plate, various optical sheets, and a reflector) of such a backlight unit are known and are not particularly limited.

A black matrix 241 may be provided under the transparent substrate 240 and may have openings and hide a gate line, a data line, and a thin film transistor of the wire plate on the lower substrate. For example, the black matrix 241 may have a grid shape. The photoluminescent layer 230 may be provided in the opening of the black matrix 241 and has a nanoparticle-polymer composite pattern including a first region R configured to emit a first light (e.g., a red light), a second region G configured to emit a second light (e.g., a green light), and a third region B configured to emit/transmit a third light, for example a blue light. If desired, the photoluminescent layer may further include at least a fourth region. The fourth region may include a quantum dot that emits light of a different color from the light emitted from the first to third regions (e.g., cyan, magenta, and yellow light).

In the photoluminescent layer 230, sections forming the pattern may be repeated corresponding to pixel areas formed on the lower substrate. A transparent common electrode 231 may be provided on the photoluminescent layer 230.

The third region (B) configured to emit/transmit a blue light may be a transparent color filter that does not change the emission spectrum of the light source. In this case, the blue light emitted from the backlight unit may enter in a polarized state and may be emitted through the polarizing plate and the liquid crystal layer as is. If needed, the third region may include a quantum dot emitting a blue light.

As described herein, if desired, the display device or light emitting device according to an embodiment may further include an excitation light blocking layer or a first optical filter layer (hereinafter, referred to as a first optical filter layer). The first optical filter layer may be disposed between the bottom surface of the first region (R) and the second region (G) and the substrate (e.g., the upper substrate 240) or on the upper surface of the substrate. The first optical filter layer may be a sheet having an opening in a portion corresponding to a pixel area (third region) displaying blue, and thus may be formed in portions corresponding to the first and second regions. That is, the first optical filter layer may be integrally formed at positions other than the position overlapped with the third region as shown in FIGS. 3A, 3B, 6 and/or 7A, but is not limited thereto. Two or more first optical filter layers may be spaced apart from each other at positions overlapped with the first and second regions, and optionally, the third region. When the light source includes a green light emitting device, a green light blocking layer may be disposed on the third region.

The first optical filter layer may block light, for example, in a predetermined wavelength region in the visible light region and may transmit light in the other wavelength regions, and for example, it may block a blue light (or a green light) and may transmit light except the blue light (or the green light). The first optical filter layer may transmit, for example, a green light, a red light, and/or a yellow light that is a mixed color thereof. The first optical filter layer may transmit a blue light and block a green light, and may be disposed on the blue light emitting pixel.

The first optical filter layer may substantially block excitation light and transmit light in a desired wavelength region. The transmittance of the first optical filter layer for the light in a desired wavelength range may be greater than or equal to about 70%, greater than or equal to about 80%, greater than or equal to about 90%, or even about 100%.

The first optical filter layer configured to selectively transmit a red light may be disposed at a position overlapped with the red light emitting section, and the first optical filter layer configured to selectively transmit a green light may be disposed at a position overlapped with the green light emitting section. The first optical filter layer may include a first filter region that blocks (e.g., absorbs) the blue light and the red light and selectively transmits light of a predetermined range (e.g., greater than or equal to about 500 nm, greater than or equal to about 510 nm, or greater than or equal to about 515 nm to less than or equal to about 550 nm, less than or equal to about 545 nm, less than or equal to about 540 nm, less than or equal to about 535 nm, less than or equal to about 530 nm, less than or equal to about 525 nm, or less than or equal to about 520 nm); a second filter region that blocks (e.g., absorbs) a blue light and a green light and selectively transmits light of a predetermined range (e.g., greater than or equal to about 600 nm, greater than or equal to about 610 nm, or greater than or equal to about 615 nm to less than or equal to about 650 nm, less than or equal to about 645 nm, less than or equal to about 640 nm, less than or equal to about 635 nm, less than or equal to about 630 nm, less than or equal to about 625 nm, or less than or equal to about 620 nm); or the first filter region and the second filter region. In an embodiment, the light source may emit a blue and a green mixed light, and the first optical filter layer may further include a third filter region that selectively transmits a blue light and blocks a green light.

The first filter region may be disposed at a position overlapped with the green light emitting section. The second filter region may be disposed at a position overlapped with the red light emitting section. The third filter region may be disposed at a position overlapped with the blue light emitting section.

The first filter region, the second filter region, and, optionally, the third filter region may be optically isolated. Such a first optical filter layer may contribute to improvement of color purity of the display device.

The display device may further include a second optical filter layer (e.g., a recycling layer of red/green light or yellow light) that is disposed between the photoluminescent layer and the liquid crystal layer (e.g., between the photoluminescent layer and the upper polarizing plate), transmits at least a portion of the third light (excitation light), and reflects at least a portion of the first light and/or the second light. The first light may be a red light, the second light may be a green light, and the third light may be a blue light. The second optical filter layer may transmit only the third light (B) in a blue light wavelength region having a wavelength region of less than or equal to about 500 nm and light in a wavelength region of greater than about 500 nm, which is green light (G), yellow light, red light (R), or the like, may be not passed through the second optical filter layer and reflected. The reflected green light and red light may pass through the first and second regions to be emitted to the outside of the display device.

The second optical filter layer or the first optical filter layer may be formed as an integrated layer having a relatively planar surface.

The first optical filter layer may include a polymer thin film including a dye and/or a pigment absorbing light in a wavelength which is to be blocked. The second optical filter layer or the first optical filter layer may include a single layer having a low refractive index, and may be, for example, a transparent thin film having a refractive index of less than or equal to about 1.4:1, less than or equal to about 1.3, or less than or equal to about 1.2. The second optical filter layer or the first optical filter layer having a low refractive index may include, for example, a porous silicon oxide, a porous organic material, a porous organic-inorganic composite, or the like, or a combination thereof.

The first optical filter layer or the second optical filter layer may include a plurality of layers having different refractive indexes. The first optical filter layer or the second optical filter layer may be formed by laminating two layers having different refractive indexes. For example, the first/second optical filter layer may be formed by alternately laminating a material having a high refractive index and a material having a low refractive index.

In an embodiment, the electronic device may include a device including the above-described semiconductor nanocrystal or a nanoparticle including the same (e.g., a light emitting device such as an electroluminescent device, or an optoelectronic device such as an optical sensor or a photodetector).

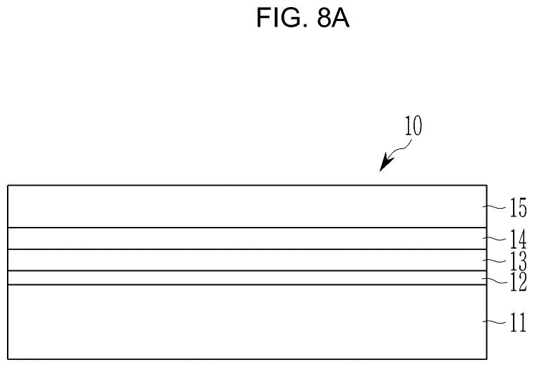

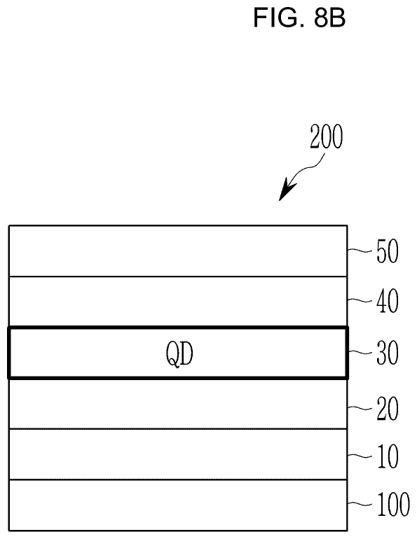

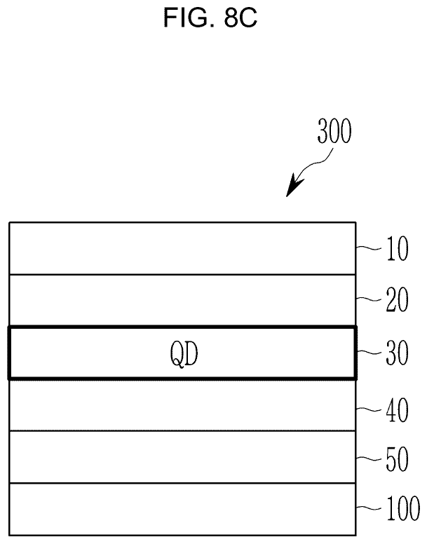

Referring to FIG. 8A, an electronic device 10 includes a first electrode 11 and a second electrode 15 that face each other, and an active layer 13 positioned between the first electrode 11 and the second electrode 15, the active layer including the above-described semiconductor nanoparticles.

In an embodiment, the electronic device may be an electroluminescent device. The semiconductor nanoparticles of the active layer 13 may serve as an emission layer in which electrons and holes injected from the first electrode 11 and the second electrode 15 recombine to form an exciton, and light of a certain wavelength may be emitted by the energy of the formed exciton. In addition, the electronic device may be a photodetector or a solar cell. Specifically, the semiconductor nanoparticles of the active layer 13 may serve as a light absorption layer that absorbs external photons and separates them into electrons and holes to provide the electrons and holes to the first electrode 11 and the second electrode 15.

A hole auxiliary layer 12 may be positioned between the first electrode 11 and the active layer 13, and an electron auxiliary layer 14 may be positioned between the second electrode 15 and the active layer 13.

The electronic device 10 may further include a substrate (not shown). The substrate may be disposed on the side of the first electrode 11 or on the side of the second electrode 15. The substrate may be a substrate including an insulating material (e.g., an insulating transparent substrate).

In addition, the substrate may include various polymers such as glass, polyester (e.g., polyethylene terephthalate (PET), polyethylene naphthalate (PEN)), polycarbonate, polyacrylate, polyimide, polyamideimide, polysiloxane (e.g., PDMS), inorganic materials such as Al₂O₃ and ZnO, or a combination thereof, and may be made of a silicon wafer. The term “transparent” may mean that the transmittance of light of a certain wavelength (e.g., light emitted from the semiconductor nanocrystal or the nanoparticle including the same) is greater than or equal to about 85%, greater than or equal to about 88%, greater than or equal to about 90%, greater than or equal to about 95%, greater than or equal to about 97%, or greater than or equal to about 99%. The thickness of the substrate may be appropriately selected in consideration of the substrate material and is not particularly limited. The transparent substrate may be flexible.

One of the first electrode 11 and the second electrode 15 is an anode, and the other is a cathode. For example, the first electrode 11 may be the anode, and the second electrode 15 may be the cathode.

The first electrode 11 may be made of a conductor, for example, a metal, a conductive metal oxide, or a combination thereof. The first electrode 11 may be made of a metal such as nickel, platinum, vanadium, chromium, copper, zinc, or gold, or an alloy thereof; a conductive metal oxide such as zinc oxide, indium oxide, tin oxide, indium tin oxide (ITO), indium zinc oxide (IZO), or fluorine-doped tin oxide; or a combination of a metal and an oxide such as ZnO and Al, or SnO₂ and Sb, but is not limited thereto.

The second electrode 15 may be made of a conductor, for example, a metal, a conductive metal oxide, and/or a conductive polymer. The second electrode 15 may include, for example, a metal such as aluminum, magnesium, calcium, sodium, potassium, titanium, indium, yttrium, lithium, gadolinium, silver, gold, platinum, tin, lead, cesium, or barium, or an alloy thereof, or a multilayer structure material such as LiF/Al, lithium oxide (Li₂O)/Al, Liq/Al, LiF/Ca, and BaF₂/Ca, but is not limited thereto. The conductive metal oxide may be the same as described above.

The work functions of the first electrode 11 and the second electrode 15 are not particularly limited and may be appropriately selected. The work function of the first electrode 11 may be higher or lower than that of the second electrode 15.

At least one of the first electrode 11 and the second electrode 15 may be a light-transmitting electrode. The light-transmitting electrode may be made of a conductive metal oxide such as zinc oxide, indium oxide, tin oxide, indium tin oxide (ITO), indium zinc oxide (IZO), or fluorine-doped tin oxide, or a single layer or a plurality of layers of a thin metal film. When one of the first electrode 11 and the second electrode 15 is a non-light-transmitting electrode, it may be made of an opaque conductor such as aluminum (Al), silver (Ag), or gold (Au).

The thickness of the first electrode 11 and/or the second electrode 15 is not particularly limited and may be appropriately selected in consideration of device efficiency. For example, the thickness of the electrode may be greater than or equal to about 5 nm, for example, greater than or equal to about 50 nm and less than or equal to about 100 μm, for example, less than or equal to about 10 μm, less than or equal to about 1 μm, less than or equal to about 900 nm, less than or equal to about 500 nm, or less than or equal to about 100 nm.

The active layer 13 includes the semiconductor nanocrystal described herein or a nanoparticle including the same. The active layer 13 may include a monolayer or a plurality of monolayers of semiconductor nanoparticle layers. The plurality of monolayer layers may be greater than or equal to about 2 layers, greater than or equal to about 3 layers, or greater than or equal to about 4 layers, and less than or equal to about 20 layers, less than or equal to about 10 layers, less than or equal to about 9 layers, less than or equal to about 8 layers, less than or equal to about 7 layers, or less than or equal to about 6 layers. The active layer 13 may have a thickness greater than or equal to about 5 nm, for example, greater than or equal to about 10 nm, greater than or equal to about 20 nm, or greater than or equal to about 30 nm, and less than or equal to about 200 nm, for example, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The active layer 13 may have a thickness of about 10 nm to about 150 nm, about 10 nm to about 100 nm, or about 10 nm to about 50 nm.

The electronic device 10 may further include a hole auxiliary layer 12. The hole auxiliary layer 12 is positioned between the first electrode 11 and the active layer 13. The hole auxiliary layer 12 may include a hole injection layer, a hole transport layer, an electron blocking layer (EBL), or a combination thereof. The hole auxiliary layer 12 may be a single-component layer or may have a multilayer structure in which adjacent layers include different components.

The HOMO energy level of the hole auxiliary layer 12 may have a HOMO energy level that can be matched with the HOMO energy level of the active layer 13 in order to enhance the mobility of holes transferred from the hole auxiliary layer 12 to the active layer 13. For example, the hole auxiliary layer 12 may include a hole injection layer located closer to the first electrode 11 and a hole transport layer located closer to the active layer 13.

The material included in the hole auxiliary layer 12 (e.g., a hole transport layer or a hole injection layer) is not particularly limited and may include, for example, Poly(9,9-dioctyl-fluorene-co-N-(4-butylphenyl)-diphenylamine) (TFB), polyarylamine, poly(N-vinylcarbazole), poly(3,4-ethylenedioxythiophene) (PEDOT), poly(3,4-ethylenedioxythiophene):polystyrene sulfonate (PEDOT:PSS), polyaniline, polypyrrole, N, N,N′,N′-tetrakis(4-methoxyphenyl)-benzidine (TPD), 4-bis [N-(1-naphthyl)-N-phenyl-amino]biphenyl (α-NPD), m-MTDATA (4,4′,4″-Tris [phenyl(m-tolyl)amino]triphenylamine), 4,4′,4″-tris(N-carbazolyl)-triphenylamine (TCTA), 1,1-bis [(di-4-tolylamino)phenyl]cyclohexane (TAPC), a p-type metal oxide (e.g., NiO, WO3, MoO₃, etc.), carbon-containing materials such as graphene oxide, and a combination thereof, but is not limited thereto.

When an electron blocking layer (EBL) is used, the electron blocking layer (EBL) may include poly(3,4-ethylenedioxythiophene):poly(styrenesulfonate) (PEDOT:PSS), Poly(9,9-dioctyl-fluorene-co-N-(4-butylphenyl)-diphenylamine) (TFB), polyarylamine, poly(N-vinylcarbazole), polyaniline, polypyrrole, N,N,N′,N′-tetrakis(4-methoxyphenyl)-benzidine (TPD), 4-bis [N-(1-naphthyl)-N-phenyl-amino]biphenyl (α-NPD), m-MTDATA, 4,4′,4″-tris(N-carbazolyl)-triphenylamine (TCTA), and a combination thereof, but is not limited thereto.

In the hole auxiliary layer(s), the thickness of each layer may be appropriately selected. For example, the thickness of each layer may be greater than or equal to about 5 nm, greater than or equal to about 10 nm, greater than or equal to about 15 nm, or greater than or equal to about 20 nm, and less than or equal to about 50 nm, for example, less than or equal to about 40 nm, less than or equal to about 35 nm, or less than or equal to about 30 nm, but is not limited thereto.

The electron auxiliary layer 14 may be positioned between the active layer 13 and the second electrode 15. The electron auxiliary layer 14 may include, for example, an electron injection layer (EIL) that facilitates injection of electrons, an electron transport layer (ETL) that facilitates transport of electrons, a hole blocking layer (HBL) that blocks the movement of holes, or a combination thereof. For example, an electron injection layer may be disposed between the electron transport layer and the cathode 15. For example, the hole blocking layer (HBL) may be disposed between the active layer and the electron transport (injection) layer, but is not limited thereto. The thickness of each layer may be appropriately selected, and for example, the thickness of each layer may be greater than or equal to about 1 nm and less than or equal to about 500 nm, but is not limited thereto. The electron injection layer may be an organic layer formed by deposition, and the electron transport layer may include inorganic oxide nanoparticles.

The electron transport layer (ETL) may include, for example, 1,4,5,8-naphthalene-tetracarboxylic dianhydride (NTCDA), bathocuproine (BCP), tris [3-(3-pyridyl)-mesityl]borane (3TPYMB), LiF, Alq₃, Gaq₃, Inq₃, Znq₂, Zn(BTZ)₂, BeBq₂, ET204 (8-(4-(4,6-di(naphthalen-2-yl)-1,3,5-triazin-2-yl)phenyl) quinolone), 8-hydroxyquinolinato lithium (Liq), an n-type metal oxide (e.g., ZnO, HfO₂), and a combination thereof, but is not limited thereto.

In addition, the electron transport layer (ETL) may include a plurality of nanoparticles. The nanoparticles may include a metal oxide including zinc, for example, zinc oxide, zinc magnesium oxide, or a combination thereof. The metal oxide may include Zn₁₋ₓMₓO (where M is Mg, Ca, Zr, W, Li, Ti, Y, Al, or a combination thereof, and 0≤x≤0.5). In this formula, x may be greater than or equal to about 0.01 and less than or equal to about 0.3, for example, less than or equal to about 0.25, less than or equal to about 0.2, or less than or equal to about 0.15. The absolute value of the LUMO of the above-described semiconductor nanocrystal or a nanoparticle including the same in the active layer may be smaller than the absolute value of the LUMO of the metal oxide. The (average) size of the nanoparticle may be greater than or equal to about 1 nm, for example, greater than or equal to about 1.5 nm, greater than or equal to about 2 nm, greater than or equal to about 2.5 nm, or greater than or equal to about 3 nm, and less than or equal to about 10 nm, less than or equal to about 9 nm, less than or equal to about 8 nm, less than or equal to about 7 nm, less than or equal to about 6 nm, or less than or equal to about 5 nm.

The hole blocking layer (HBL) may include, for example, 1,4,5,8-naphthalene-tetracarboxylic dianhydride (NTCDA), bathocuproine (BCP), tris [3-(3-pyridyl)-mesityl]borane (3TPYMB), LiF, Alq₃, Gaq₃, Inq₃, Znq₂, Zn(BTZ)₂, BeBq₂, or a combination thereof, but is not limited thereto.

The thickness of each of the electron auxiliary layer 14 (e.g., an electron injection layer, an electron transport layer, or a hole blocking layer) may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

Referring to FIG. 8B, an electronic device according to an embodiment may have a normal structure. The electroluminescent device 200 may include an anode 10 disposed on a transparent substrate 100 and a cathode 50 facing the anode 10. The anode 10 may include a metal oxide-based transparent electrode, and the cathode 50 facing the anode 10 may include a conductive metal having a low work function. For example, the anode (positive electrode) may be an indium tin oxide (ITO) electrode (work function of about 4.6 to about 5.1), and the cathode (negative electrode) 50 may be an electrode including magnesium (Mg, work function of about 3.66), aluminum (Al, work function of about 4.28), or a combination thereof. In addition, a hole auxiliary layer 20 may be disposed between the anode 10 and an active layer (or referred to as semiconductor nanoparticle active layer or nanoparticle active layer) 30 of semiconductor nanocrystals or nanoparticles including the same. The hole auxiliary layer 20 may include a hole injection layer and/or a hole transport layer, and the hole injection layer may be positioned closer to the anode 10, while the hole transport layer may be positioned closer to the active layer of semiconductor nanocrystals or nanoparticles including the same. In addition, an electron auxiliary layer 40 may be disposed between the active layer 30 of semiconductor nanocrystals or nanoparticles including the same and the cathode 50. The electron auxiliary layer 40 may include an electron injection layer and/or an electron transport layer, and the electron injection layer may be positioned closer to the cathode 50, while the electron transport layer may be positioned closer to the active layer 30 of semiconductor nanocrystals or nanoparticles including the same.

Referring to FIG. 8C, an electronic device of another embodiment may have an inverted structure. An electroluminescent device 300 of the inverted structure may include a cathode 50 disposed on a transparent substrate 100 and an anode 10 facing the cathode 50. The cathode 50 may include a transparent electrode based on a metal oxide, and the anode 10 facing the cathode 50 may include a conductive metal having a high work function. For example, the anode 10 may be an indium tin oxide (ITO) electrode (work function of about 4.6 eV to about 5.1 eV), and the cathode 50 may be an electrode including gold (Au, work function of about 5.1 eV), silver (Ag, work function of about 4.26 eV), aluminum (Al, work function of about 4.28 eV), or a combination thereof.

In addition, an electron auxiliary layer 40 may be disposed between a semiconductor nanoparticle active layer 30 and the cathode 50. The electron auxiliary layer 40 may include an electron injection layer and/or an electron transport layer, wherein the electron injection layer may be disposed closer to the cathode 50, and the electron transport layer may be disposed closer to a semiconductor nanocrystal or the nanoparticle active layer 30 including the same. The electron auxiliary layer 40 (for example, the electron transport layer) may include a metal oxide, and may include crystalline Zn oxide or an n-type doped metal oxide. Further, a hole auxiliary layer 20 may be disposed between the anode 10 and a semiconductor nanocrystal or the nanoparticle active layer 30 including the same. The hole auxiliary layer 20 may include a hole injection layer and/or a hole transport layer, wherein the hole injection layer may be disposed closer to the anode 10, and the hole transport layer may be disposed closer to the semiconductor nanocrystal or the nanoparticle active layer 30 including the same. The hole transport layer may include TFB, PVK, or a combination thereof, and the hole injection layer may include MoO₃ or another p-type metal oxide.

The electroluminescent device emits light of a certain wavelength generated in an active layer 30 to the outside through a light-transmissive electrode and a transparent substrate. For example, referring to FIG. 8B, when a transparent electrode based on a metal oxide (for example, indium tin oxide (ITO)) as a light-transmissive electrode is applied to an anode 10, light formed in the active layer is emitted to the outside through the anode 10 and the transparent substrate 100. Referring to FIG. 8C, when a transparent electrode based on a metal oxide (for example, indium tin oxide (ITO)) as a light-transmissive electrode is applied to a cathode 50, light formed in the active layer is emitted to the outside through the cathode 50 and the transparent substrate 100.

The above-described electronic device may be manufactured by an appropriate method. For example, the electroluminescent device may be manufactured by forming a hole auxiliary layer (or an electron auxiliary layer) on a substrate on which an electrode is formed, forming an active layer including semiconductor nanocrystals or nanoparticles including the same (for example, a pattern of the above-described semiconductor nanocrystals or nanoparticles including the same), and forming an electron auxiliary layer (or a hole auxiliary layer) and an electrode on the active layer. The electrode, the hole auxiliary layer, and the electron auxiliary layer may each be formed independently by an appropriate method, and may be formed, for example, by deposition or coating, but are not particularly limited thereto.

Hereinafter, the exemplary embodiments are illustrated in further detail with reference to examples. However, embodiments of the present disclosure are not limited to the examples.

### EXAMPLES

### Analysis Methods

### [1] Photoluminescence Analysis

A photoluminescence (PL) spectrum of the nanoparticles produced and a composite including the same was obtained using a Hitachi F-7000 spectrophotometer at a predetermined excitation wavelength.

### [2] UV Spectroscopic Analysis

UV spectroscopic analysis was performed using an Agilent Cary 5000 spectrometer to obtain a UV-Visible absorption spectrum.

### [3] ICP Analysis

Inductively Coupled Plasma Atomic Emission Spectroscopy (ICP-AES) analysis was performed using a Shimadzu ICPS-8100.

### Example 1

Selenium (Se) powder was dispersed in trioctylphosphine to prepare Se-TOP (concentration: 0.4 molar (M)). In a reaction flask containing 150 milliliters (ml) of oleylamine, oleic acid, indium acetate (In (ac) 3) as an indium precursor, and Se-TOP as a selenium precursor were added to prepare a reaction solution. The reaction solution was subjected to vacuum treatment at 120° C. for 10 minutes, and N₂ was supplied into the reaction flask. Subsequently, while heating the reaction solution to a reaction temperature, a zinc precursor (zinc oleate) was added to the reaction solution at 210° C. The reaction was carried out for 30 minutes while maintaining the reaction temperature at 280° C. After completion of the reaction, the temperature of the reaction solution was cooled to room temperature, and a poor solvent (ethanol) was added into the reaction flask to promote precipitation of particles. The resulting particles were dispersed in hexane.

In the reaction solution, a mole ratio of indium precursor to selenium precursor was 10:1. The used amount of the indium precursor in the reaction solution was 0.05 mol per 1 mol of zinc precursor.

ICP-AES analysis was performed on the produced particles, and the results (mole ratio) are summarized in Table 1. Photoluminescence analysis performed on the produced particles confirmed a trap emission peak (peak emission wavelength: 500 nm).

### Example 2

Nanoparticles were prepared in the same manner as in Example 1, except that the used amount of the indium precursor was 0.1 mol per 1 mol of zinc precursor. ICP-AES analysis was performed on the produced particles, and the results (mole ratio) are summarized in Table 1.

### Example 3

Nanoparticles were prepared in the same manner as in Example 1, except that the used amount of the indium precursor was 0.15 mol per 1 mol of zinc precursor. ICP-AES analysis was performed on the produced particles, and the results (mole ratio) are summarized in Table 1.

### Example 4

Nanoparticles were prepared in the same manner as in Example 1, except that the used amount of the indium precursor was 0.175 mol per 1 mol of zinc precursor. ICP-AES analysis was performed on the produced particles, and the results (mole ratio) are summarized in Table 1.

### Example 5

Nanoparticles were prepared in the same manner as in Example 1, except that the used amount of the indium precursor was 0.2 mol per 1 mol of zinc precursor. ICP-AES analysis was performed on the produced particles, and the results (mole ratio) are summarized in Table 1.

### Example 6

Nanoparticles were prepared in the same manner as in Example 1, except that the used amount of the indium precursor was 0.25 mol per 1 mol of zinc precursor. ICP-AES analysis was performed on the produced particles, and the results (mole ratio) are summarized in Table 1.

TABLE 1

| | | | | | | | Photoluminescent |
|---|---|---|---|---|---|---|---|
| | | | | | | | peak emission |
| | | | | | | Indium | wavelength |
| | In:Se | Zn:Se | In:(Zn + In) | Zn:In | CBV | content | (nm) |
| Example 1 | 0.024:1 | 1.065:1 | 0.109:1 | 8.71:1 | 1.24 | 5% | 500 |
| Example 2 | 0.130:1 | 0.745:1 | 0.224:1 | 3.37:1 | 1.06 | 10% | 500 |
| Example 3 | 0.216:1 | 0.743:1 | 0.283:1 | 2.53:1 | 1.18 | 14% | 507 |
| Example 4 | 0.293:1 | 0.590:1 | 0.364:1 | 1.75:1 | 1.1 | 17% | 512 |
| Example 5 | 0.337:1 | 0.440:1 | 0.471:1 | 1.12:1 | 1.03 | 20% | 511 |
| Example 6 | 0.392:1 | 0.421:1 | 0.503:1 | 0.99:1 | 1.06 | 23% | 530 |

CBV: charge balance value
Indium content (%): [Indium molar amount / (Indium molar amount + Selenium molar amount + Zinc molar amount)] × 100

### Example 7

Selenium (Se) powder was dispersed in trioctylphosphine to prepare Se-TOP as a selenium precursor (concentration: 0.4 M). As a reaction solvent, a reaction solution was prepared in a reaction flask containing 150 ml of oleylamine, to which oleic acid, indium acetate (In (ac) 3) as an indium precursor, and zinc acetate (Zn (ac) 2) as a zinc precursor were added. The reaction solution was subjected to vacuum treatment at 120° C. for 10 minutes, and the N₂ was supplied into the reaction flask. The reaction solution was then heated to the reaction temperature, and when the temperature reached 280° C., the selenium precursor was added to the reaction solution. The reaction was carried out for 10 minutes while maintaining the reaction temperature at 280° C. After completion of the reaction, the temperature of the reaction solution was cooled to room temperature, and a poor solvent (ethanol) was added into the reaction flask to promote precipitation of particles. The resulting particles were dispersed in hexane. Photoluminescence analysis performed on the produced particles confirmed a trap emission peak (peak emission wavelength: 654 nm).

In the reaction solution, a mole ratio of indium precursor to selenium precursor was 1:2. The used amount of the indium precursor was 0.5 mol per 1 mol of zinc precursor.

### Comparative Example 1

Selenium (Se) powder was dispersed in trioctylphosphine to prepare Se-TOP as a selenium precursor (concentration: 0.4 M). As a reaction solvent, a reaction solution was prepared in a reaction flask containing 150 ml of trioctylamine, into which oleic acid and oleylamine were added. The reaction solution was subjected to vacuum treatment at 120° C. for 10 minutes, and the inside of the reaction flask was replaced with N₂. The reaction solution was heated to 240° C., and diethyl zinc as a zinc precursor and the prepared selenium precursor were added to the reaction solution. The reaction was carried out for 10 minutes while maintaining the reaction temperature at 280° C. After completion of the reaction, the temperature of the reaction solution was cooled to room temperature, and a poor solvent (ethanol) was added into the reaction flask to promote precipitation of particles. The resulting particles were dispersed in hexane.

### Comparative Example 2

Nanoparticles were prepared in the same manner as in Example 1, except that trioctylamine was used instead of oleylamine.

### Comparative Example 3

Nanoparticles were prepared in the same manner as in Example 1, except that dodecanethiol was used as an organic ligand instead of oleic acid.

### Comparative Example 4

Nanoparticles were prepared in the same manner as in Example 1, except that the reaction temperature was 220° C.

### Experimental Example 1: PL Analysis

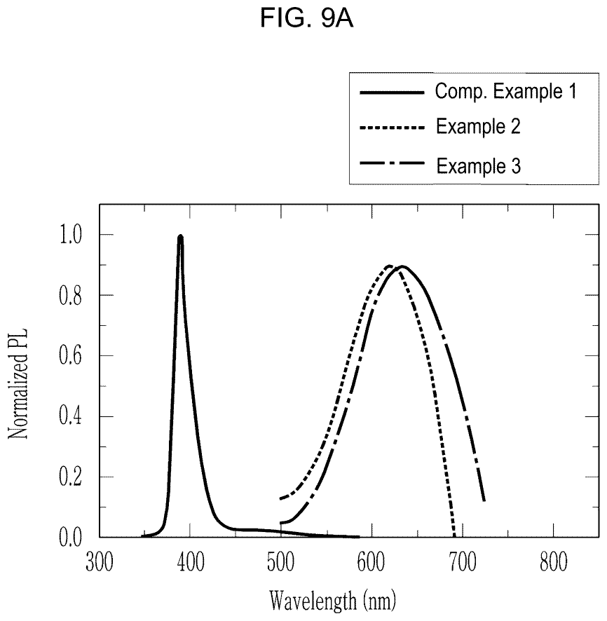

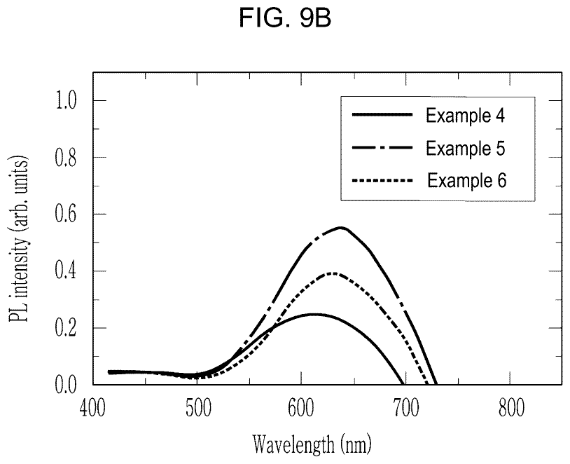

(1) For the nanoparticles obtained in Comparative Example 1 and Examples 2 to 6, photoluminescence spectroscopy (excitation wavelength: 400 nm) analysis was performed, and the results are summarized in FIGS. 9A and 9B and Table 1. From FIGS. 9A and 9B and Table 1, it can be confirmed that the nanoparticles of Comparative Example 1 did not exhibit a trap emission peak, whereas the nanoparticles of the Examples exhibited a trap emission peak with relatively high intensity, and that the emission intensity may vary depending on the indium content.

(2) Photoluminescence analysis (excitation wavelength: 320 nm) performed on the nanoparticles obtained in Example 6 confirmed that they exhibited a trap emission peak at substantially the same position as that at the excitation wavelength of 400 nm.

(3) The nanoparticles prepared in Example 1 were confirmed to exhibit increased photoluminescence intensity compared with the nanoparticles prepared in Example 7.

(4) Photoluminescence spectroscopy (excitation wavelength: 400 nm) analysis performed on the nanoparticles prepared in Comparative Examples 2 and 4 confirmed that they did not exhibit a trap emission peak.

The nanoparticles of Comparative Example 3 exhibited emission, but its intensity was significantly lower compared with the Examples, because in the Examples the emission of the nanoparticles increased with an increase in the reaction time, whereas in Comparative Example 3 no increase in emission with reaction time was observed.

### Experimental Example 2: UV-Vis Absorption Spectroscopy

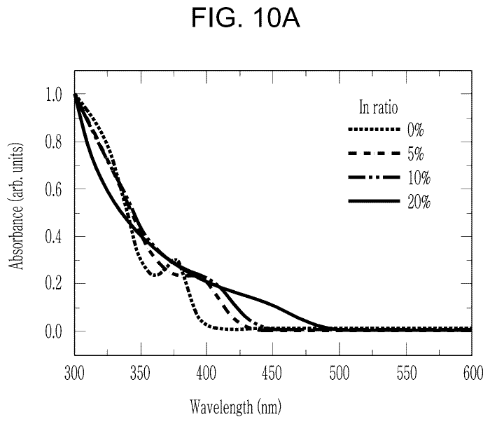

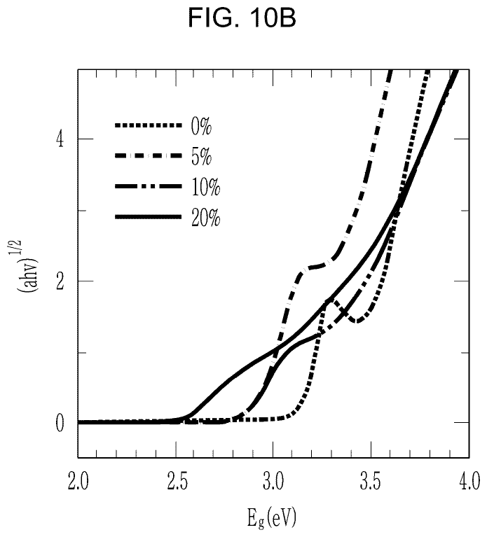

For the nanoparticles obtained in Comparative Example 1 (In ratio 0%) and Example 1 (In ratio 5%), Example 2 (In ratio 10%), and Example 5 (In ratio 20%), UV-Vis absorption spectroscopy analysis was performed, and the results are summarized in FIGS. 10A and 10B and Table 2.

TABLE 2

| | First absorption peak | Bandedge |
|---|---|---|
| | wavelength (nm) | energy (eV) |
| Example 1 | 394 | 2.90 |
| Example 2 | 400 | 2.80 |
| Example 5 | 432 | 2.48 |
| Comparative | 375 | 3.12 |
| Example 1 | | |

From the results of FIGS. 10A and 10B and Table 2, it can be confirmed that the nanoparticles of the Examples exhibited a first absorption peak, and that the wavelength of the first absorption peak and the absorption edge varied depending on the indium content.

### Experimental Example 3: Transmission Electron Microscopy (TEM) Analysis

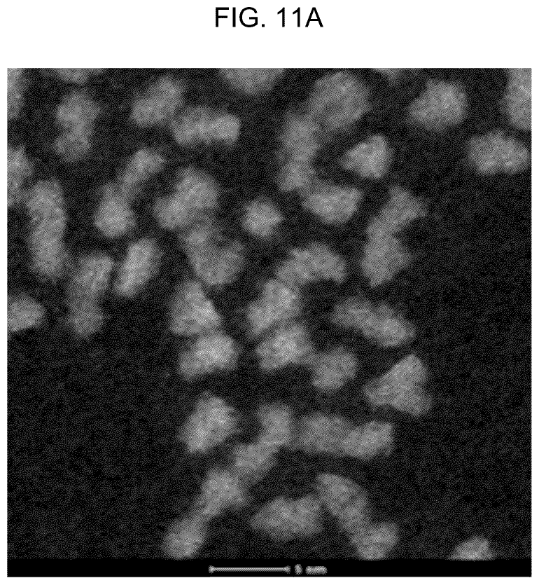

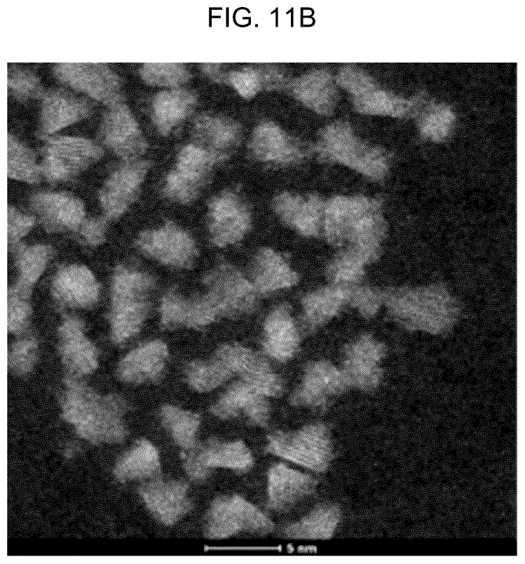

Transmission electron microscopy analysis was performed on the particles prepared in Example 1 and Example 2, and the results are shown in FIGS. 11A and 11B. It was confirmed that the sizes of the particles prepared in Example 1 and Example 2 were about 3.59 nm and about 3.31 nm, respectively.

While this disclosure has been described in connection with what is presently considered to be practical embodiments, it is to be understood that the present subject matter is not limited to the disclosed exemplary embodiments. On the contrary, it is intended to cover various modifications and equivalent arrangements included within the spirit and scope of the appended claims.

What is claimed is:

1. A nanoparticle,
the nanoparticle comprising a semiconductor nanocrystal including zinc, indium, and selenium,
wherein in the semiconductor nanocrystal, a mole ratio of indium to selenium is greater than or equal to about 0.1:1 and less than or equal to about 0.5:1,
wherein the nanoparticle does not comprise cadmium, and the nanoparticle is configured to emit a first light, and a peak emission wavelength of the first light is greater than or equal to about 480 nanometers and less than or equal to about 700 nanometers.

2. The nanoparticle of claim 1,
wherein the semiconductor nanocrystal does not comprise silver, copper, manganese, cobalt, or a combination thereof.

3. The nanoparticle of claim 1,
wherein in the semiconductor nanocrystal, a mole ratio of indium to selenium is greater than or equal to about 0.13:1 and less than or equal to about 0.43:1.

4. The nanoparticle of claim 1,
wherein in the semiconductor nanocrystal, a mole ratio of indium to a total of zinc and indium is greater than or equal to about 0.02:1 and less than or equal to about 0.8:1.

5. The nanoparticle of claim 1,
wherein in the semiconductor nanocrystal, a mole ratio of zinc to selenium is greater than or equal to about 0.35:1 and less than or equal to about 1.34:1.

6. The nanoparticle of claim 1,
wherein in the semiconductor nanocrystal, a charge balance value obtained by the following formula is greater than or equal to about 0.8 and less than or equal to about 1.8:
Charge balance value={2[Zn]+3[In]}/(2[Se])
where [Zn], [In], and [Se] are molar amounts of zinc, indium, and selenium, respectively, in the semiconductor nanocrystal or in the nanoparticle.

7. The nanoparticle of claim 1,
wherein the first light has a full width at half maximum of greater than or equal to about 50 nanometers and less than or equal to about 200 nanometers, and
wherein the peak emission wavelength of the first light is greater than or equal to about 500 nanometers and less than or equal to about 680 nanometers.

8. The nanoparticle of claim 1,
wherein in a UV-Vis absorption spectrum, the nanoparticle has an absorption edge in a range of greater than or equal to about 380 nanometers and less than or equal to about 540 nanometers.

9. The nanoparticle of claim 1,
wherein in a UV-Vis absorption spectrum, the nanoparticle has a first absorption peak wavelength of greater than or equal to about 380 nanometers and less than or equal to about 500 nanometers.

10. The nanoparticle of claim 1,
wherein the nanoparticle has a pyramidal shape.

11. A method of preparing the nanoparticle of claim 1, which comprises
contacting an indium precursor, a selenium precursor, and a zinc precursor at a reaction temperature in the presence of an organic ligand in an organic solvent,
wherein the reaction temperature is greater than or equal to about 230° C. and less than or equal to about 380° C.

12. The method of claim 11,
wherein the method comprises preparing a reaction solution including the indium precursor, the selenium precursor, and the organic ligand in the organic solvent; heating the reaction solution to the reaction temperature; and adding the zinc precursor to the reaction solution.

13. The method of claim 11, wherein the reaction solution does not comprise dodecanethiol.

14. The method of claim 11, wherein the organic solvent comprises a C5 to C40 primary amine compound, and
wherein an amount of the primary amine compound is greater than or equal to about 30% and less than or equal to about 100% based on a total volume of the organic solvent.

15. The method of claim 11, wherein the reaction temperature is greater than or equal to about 280° C. and less than or equal to about 320° C.

16. A composition comprising the nanoparticle of claim 1 and a liquid vehicle.

17. A composite comprising a matrix and a plurality of nanoparticles dispersed in the matrix,
wherein the plurality of nanoparticles comprise the nanoparticle of claim 1.

18. A display device comprising the nanoparticle of claim 1.

19. An electronic device comprising:
a first electrode and a second electrode that are spaced apart from each other; and
an active layer disposed between the first electrode and the second electrode,
wherein the active layer comprises the nanoparticle of claim 1.
